(19) United States
(12) Patent Application Publication
(10) Pub. No.: US 2014/0076398 A1
(43) Pub. Date: Mar. 20, 2014

(54) SPHERICAL GRADIENT INDEX (GRIN) LENSES AND THEIR USES IN SOLAR CONCENTRATION

(71) Applicants: The Trustees of Columbia University in the City of New York, (US); Ben Gurion University of the Negev, (US)

(72) Inventors: Jeffrey Gordon, Ben-Gurion (IL); Spyros Panagiotis Kotsidas, Attiki (GR); Vijay Modi, New York, NY (US)

(73) Assignees: Ben Gurion University of the Negev, Beer Sheva (IL); The Trustees of Columbia University in the City of New York, New York, NY (US)

(21) Appl. No.: 13/741,125

(22) Filed: Jan. 14, 2013

Related U.S. Application Data
(63) Continuation of application No. PCT/US2011/050701, filed on Sep. 7, 2011.
(60) Provisional application No. 61/380,632, filed on Sep. 7, 2010.

(51) Int. Cl. G02B 3/00; H01L 31/0232; H01L 31/052; G06F 17/50

(52) U.S. Cl. CPC G02B 3/0087; G06F 17/50; H01L 31/0232; H01L 31/0524
USPC 136/259; 359/653; 703/2

(57) ABSTRACT

Spherical gradient index (GRIN) lens that can achieve perfect imaging and maximum concentration is provided. Various refractive index profiles for the GRIN lens allow the lens to be manufactured by the currently available materials and fabrication techniques. Systems and methods for photovoltaic solar concentration are provided in which the optic tracks the sun and the photovoltaic cell remains stationary. The optic of such systems and methods can include perfect imaging spherical GRIN lens to provide high flux concentration.

### CROSS REFERENCES TO RELATED APPLICATIONS

This application is a continuation of International Patent Application Serial No. PCT/US2011/050,701 filed Sep. 7, 2011 and claims priority from U.S. Provisional Application No. 61/380,632, filed Sep. 7, 2010, the disclosure of which are incorporated herein in their entireties.

### STATEMENT REGARDING FEDERALLY FUNDED RESEARCH

This invention was made with government support under the M-GRIN program, Contract No. HR0011-10-C-0110, awarded by the Defense Advanced Research Programs Agency. The government has certain rights in this invention.

### BACKGROUND

Gradient-index (GRIN) lenses are a type of optic that has a varying refractive index of the lens material. It is theoretically shown that spherical GRIN lenses having certain specific derived refractive index profiles n(r) (spherically symmetric in lens radial coordinate r) can achieve perfect imaging. However, perfect imaging GRIN lenses for optical and solar frequencies with the required n(r) have not been able to be fabricated with available materials and fabrication techniques.

Maxwell initiated the field of GRIN optics in trying to understand the fish eye. The first derivation of refractive index profiles n(r) that produce perfect imaging for a general near-field source and target was published by Luneburg (although a specific solution was provided only for a far-field source and the focus on the lens surface) [1]. Luneburg's derivation assumed that n(r) is an invertible monotonic function, devoid of discontinuities. Although successfully implemented in microwave antennas, Luneburg's solution remained an esoteric ideal for visible and IR radiation because of its severe constraints: (a) a minimum index nₘᵢₙ of unity at the lens surface, (b) a large index gradient (Δn≡nₘₐₓ−nₘᵢₙ>0.4), and (c) the focus resides on the sphere's exterior. Recent research advances in transparent polymers [2-4] have spawned materials and production techniques for the requisite ultra-thin spherical lens layers, but impose Δn<0.13 and nₘᵢₙ values that must exceed 1.4, as well as necessitating a constant-index spherical core.

Based on the fundamental relation between maximum flux concentration Cₘₐₓ and acceptance half-angle θ_{acc} at a given concentrator exit numerical aperture NAₑₓᵢₜ[5-6]: Cₘₐₓ=(NAₑₓᵢₜ/sin(θ_{acc}))², it appears that daylong solar concentration levels of the order of 10³ (or higher) cannot be realized in nominally stationary systems. Indeed, solar concentrators have realized daily-averaged flux concentration of the order of 10³ (at θ_{acc}≈1°) only with precision dual-axis tracking driven from massive pedestals [7-8]. An individual tracker can support dozens of m² of collector, weighing hundreds of kg. Here, θ_{acc} is the effective solar half-angle comprising the sun's intrinsic value of 4.7 mrad convolved with alignment inaccuracies, imperfections in the shapes of optical contours, and deviations of material properties from their design values.

In earlier solar thermal and photovoltaic concentrators, the very nature of the absorbers, or the extensive range of motion to be accommodated, precluded practical consideration of stationary absorbers with optics that tracks the sun. The evolution of concentrator photovoltaic (CPV) technology to mm-scale solar cells obviates these drawbacks and prompts revisiting the prospect of nominally stationary high-concentration optics, a collateral benefit of which would be rooftop CPV. Furthermore, there are practical micro-mechanical systems capable of the solar tracking with sub-mrad accuracy (small enough not to affect θ_{acc}), over cm dimensions, inside the module [9].

The inadequacy of conventional lenses and mirrors has long been recognized. Even nonimaging designs tailored to nominal collector stationarity succeeded in achieving a daily-averaged flux concentration of only tens of suns at high collection efficiency [10] (1 sun=1 mW/mm²)—one to two orders of magnitude below the values required for CPV.

### SUMMARY

In one aspect of the disclosed subject matter, a spherical GRIN lens is provided. The GRIN lens has a radius and a radially symmetric refractive index profile n(r), where r is the radial position within the lens and 0≦r≦1. In some embodiments, the n(r) of the lens satisfies the following: there exist rₐ and r_{b}, 0<rₐ<r_{b}<1, such that n(0)>n(rₐ), n(r_{b})>n(rₐ), and n(r_{b})>n(1). In some of these embodiments, the refractive index of the center of the GRIN lens n(0)>n(r_{b}). In other embodiments, n(0)<n(r_{b}).

In certain embodiments, the GRIN lens includes a core having a substantially constant refractive index, i.e., n(r) is substantially constant from the center of the lens to a given radius, e.g., of about 0.05 to about 0.9, or about 0.1 to about 0.6. In these embodiments, the GRIN lens can further include a portion having greater refractive index than the constant refractive index.

In some embodiments, the GRIN lens can include an outer shell having a substantially constant index. In any of the above embodiments or the embodiments described below, the surface refractive index of the GRIN lens n(1) can be greater than 1.

In certain embodiments, the variation of the refractive index across the core does not exceed 0.3, e.g., not more than 0.13. The maximum refractive index can be about 1.4 to about 2, or about 1.4 to about 1.8, or about 1.4 to about 1.6.

In some embodiments, the entire n(r) over the range of 0≦r≦1 of the spherical GRIN lens is mathematically derived from a given set of input parameters including an aperture of the lens, a desired focal length of the lens, and n(1), such that the spherical GRIN lens as a whole produces nominally perfect imaging.

In some embodiments, the n(r) of the spherical GRIN lens includes at least two portions depending on r: (1) a user prescribed portion for r_{A}≦r≦r_{B}, wherein r_{A} and r_{B}ε(0,1); (2) a portion for 0<r<r_{A} and r_{B}<r<1, where n(r) is mathematically derived from a set of input parameters including an aperture of the lens and a desired focal length of the lens such that the spherical GRIN lens as a whole produces nominally perfect imaging. In these embodiments, the user prescribed portion can be a constant over r_{A}≦r≦r_{B}, or a linear or non-linear function over r_{A}≦r≦r_{B}. Further, the user defined region can be an outer shell of the GRIN lens, e.g., 0<r_{A}<C₃, C₃ is a real number in the range of about 0.6 to about 0.95, and r_{B}=1.

The spherical GRIN lens of can be made of one or more materials whose refractive index is in the range of about 1.1 to about 2.0. The material can be polymeric, glass or other suitable material.

The spherical GRIN lens can have an aperture of smaller than 1. For example, spherical caps of the lens outside of the aperture can be symmetrically truncated. The spherical GRIN lens can have a focal length greater than or equal to 1 relative to the radius of the GRIN lens, or a focal length smaller than 1.

In some embodiments, the spherical GRIN lens produces nominally perfect imaging. The spherical GRIN lens can be incorporated as an optic component of an imaging system, a photovoltaic concentration system, a camera, a microscope, a telescope, an illumination system, and the like, as well as other applications where the role of object and image (source and target) are interchanged relative to the flux concentration applications, for example, a collimator.

In another aspect of the disclosed subject matter, a method for obtaining a radially symmetric refractive index profile n(r) of a spherical GRIN lens is provided. The method includes providing a value for each of a set of input parameters including n(1), a focal length of the lens and an aperture of the lens; and using a computer apparatus, numerically determining n(r) based on the provided values for the set of input parameters, such that the lens produces nominally perfect imaging. The value provided for the refractive index of the surface of the lens can be greater than 1, and the value provided for the aperture of the lens can be smaller than 1.

In a further aspect of the disclosed subject matter, a method for obtaining a radially symmetric refractive index profile n(r) of a spherical GRIN lens is provided. The method includes providing a predefined function for a range of r_{A}≦r≦r_{B}; providing a value for each of a set of input parameters, the parameters including a focal length of the lens and an aperture of the lens; and using a computer apparatus, numerically determining n(r) for the remaining range of r based on the provided values for the set of input parameters, such that the lens produces nominally perfect imaging.

In yet another aspect of the disclosed subject matter, a system for photovoltaic solar concentration is provided. The system includes a stationary absorber including a photovoltaic cell; a spherical gradient index (GRIN) lens, wherein the photovoltaic cell is placed at a distance from the center of the GRIN lens, the distance being equal to the focal length of the GRIN lens for the sun, and a tracking device operatively coupled to the GRIN lens. The tracking device can enable the movement of the GRIN lens to track the trajectory of the sun while maintaining the distance from the lens to the photovoltaic cell. The system can further include a backing plate having a surface to which the photovoltaic cell is affixed. The baking plate cans serve as, or comprises a heat sink. The system can further include a housing which encloses the stationary absorber, the GRIN lens, and the tracking device. The spherical GRIN lens of the system can be perfect imaging GRIN lens, and can be any of the spherical GRIN lens described above that have focal length not smaller than 1. For example, the focal length of the spherical GRIN lens can be greater than 1.73.

In another aspect of the disclosed subject matter, a method of utilizing solar energy is provided. The method includes placing a photovoltaic cell at a distance from the center of a spherical GRIN lens, the distance being equal to the focal length of the GRIN lens for the sun; and moving the GRIN lens to track the trajectory of the sun while maintaining the distance, wherein the photovoltaic cell is kept stationary during moving the GRIN lens.

In another aspect of the disclosed subject matter, a system for photovoltaic solar concentration is provided, which includes an absorber including a photovoltaic cell having a light receiving surface; a spherical gradient index (GRIN) lens, wherein the photovoltaic cell is placed at a distance from the center of the GRIN lens, the distance being equal to the focal length of the GRIN lens for the sun, and a tracking device operatively coupled to the GRIN lens and the photovoltaic cell, the tracking device being capable of moving the GRIN lens to track the trajectory of the sun and moving the photovoltaic cell such that the line connecting the center of the GRIN lens and the center of the sun is always normal to the light receiving surface of the photovoltaic cell. In this system, the GRIN lens can be a nominally perfect imaging GRIN lens. The GRIN lens can be any of the various GRIN lenses described above.

### BRIEF DESCRIPTION OF THE DRAWINGS

FIGS. 1a-1b depict geometries of ray trajectories through a perfect imaging spherical GRIN lens.

FIGS. 2a-2e depict raytraces for various perfect imaging GRIN lenses.

FIGS. 3a-3e depict refractive index profiles of the various perfect imaging GRIN lenses depicted in FIGS. 2a-2e.

FIG. 4 depicts the shell thickness of spherical GRIN lens having a constant-index shell as dependent on the focal length of the lens for a range of refractive index for the shell.

FIG. 5a depicts a refractive index profile for a spherical GRIN lens having surface refractive index of greater than 1, according to some embodiments of the disclosed subject matter.

FIG. 5b depicts raytraces of a far-field source for the spherical GRIN lens as depicted in FIG. 5a.

FIG. 6 shows certain input parameters for obtaining a refractive index profile for a spherical GRIN lens, according to some embodiments of the disclosed subject matter.

FIG. 7 depicts certain refractive index profiles for spherical GRIN lenses with a core of substantially constant refractive index, according to some embodiments of the disclosed subject matter.

FIG. 8 depicts a refractive index profile for a spherical GRIN lens having a core of substantially constant refractive index and a constant-index outer shell, according to some embodiments of the disclosed subject matter.

FIG. 9a depicts a refractive index profile for a spherical GRIN lens with a core of substantially constant refractive index, obtained as a closed-form solution according to some embodiments of the disclosed subject matter.

FIG. 9b depicts a comparison between the refractive index profile of the standard Luneburg solution with that obtained from a closed form solution for the same given aperture and focal length.

FIG. 10a depicts a photovoltaic concentration system with moving optic and stationary absorber according to some embodiments of the disclosed subject matter.

FIG. 10b depicts an arrangement of spherical GRIN lenses of a photovoltaic concentration system of the disclosed subject matter that results in uncollected radiation.

FIG. 10e depicts a compact packing of spherical GRIN lenses of a photovoltaic concentration system of the disclosed subject matter that results in mutual shading.

FIG. 10d depicts a nominally stationary photovoltaic module including a plurality of spherical GRIN lenses.

FIGS. 11a-11b depict focal spot of a spherical GRIN lens on the stationary absorber for a range of incidence angles, according to some embodiments of the photovoltaic concentration system of the disclosed subject matter.

FIG. 12 depicts loss of collectible radiation for different focal length of a spherical GRIN lens, according to some embodiments of the photovoltaic concentration system of the disclosed subject matter.

FIG. 13 depicts the dependence of the efficiency-concentration characteristic on the focal length of a spherical GRIN lens, according to some embodiments of the photovoltaic concentration system of the disclosed subject matter.

FIG. 14 depicts dispersion loss of a spherical GRIN lens for the polychromatic light of the full solar spectrum, according to some embodiments of the photovoltaic concentration system of the disclosed subject matter.

FIG. 15 depicts misalignment sensitivity of a photovoltaic concentration system of the disclosed subject matter.

FIG. 16a-c depicts the refractive index profile of an embodiment of spherical GRIN lens suitable for the photovoltaic concentration system of the disclosed subject matter.

FIG. 17 depicts the refractive index profile of another embodiment of spherical GRIN lens suitable for the photovoltaic concentration system of the disclosed subject matter.

FIG. 18a-b depicts the refractive index profile of a further embodiment of spherical GRIN lens suitable for the photovoltaic concentration system of the disclosed subject matter.

### DETAILED DESCRIPTION

In one aspect, the disclosed subject matter provides new classes of GRIN lenses that can offer nominally perfect imaging. As used herein, “nominally perfect imaging” (which is used interchangeably with “perfect imaging”) as relating to a spherical GRIN lens means that the spherical GRIN lens is devoid of geometric aberrations for a given monochromatic light of the wavelength of interest. It is understood that chromatic aberrations due to dispersion can still exist in perfect imaging lens.

In some embodiments, the GRIN lens has a radially symmetric refractive index profile n(r), where r is the radial position within the lens and 0≦r≦1 (i.e., r is a distance between a point within the lens and the center of the lens relative to the radius of the lens, hence r has a reduced or dimensionless unit, and is unity at the surface of the lens). The n(r) satisfies the following: there exist r₁ and r₂, 0<rₐ<r_{b}<1, such that n(0)>n(rₐ), n(r_{b})>n(rₐ), and n(r_{b})>n(1). The n(r) as described according to this condition encompasses a wide collection of refractive index profiles, which can be more readily appreciated when viewed in connection with the various illustrative examples, including the figures. The various parameters relating to the features of n(r) such as rₐ, r_{b}, r_{c}, r_{d}, r_{A}, r_{B}, C₁, C₂, etc., as described are radial positions along the spherical coordinate r, and are for identified in certain figures below for illustration only. It is appreciated that it is possible to identify some of these parameters at different positions on the same n(r) profile as shown.

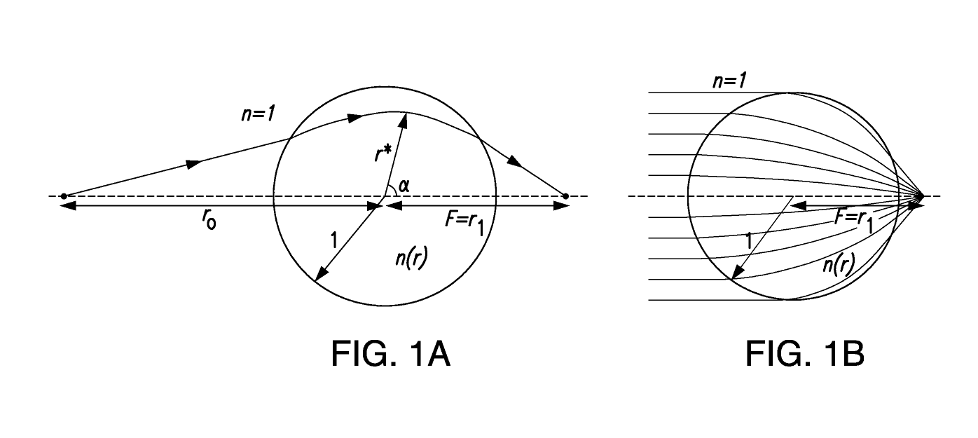

As disclosed herein, designing perfect imaging spherical GRIN lenses involves derive n(r) for a spherical lens in air (n=1 for air), that perfectly images an object comprising part of a spherical contour with radius rₒ to a spherical contour image of radius r₁, as illustrated in FIG. 1 (FIG. 1(a): Sample ray trajectory through a perfect-imaging spherical GRIN lens, from a source point at rₒ to a target point at r₁. r* denotes the closest point of approach to the origin. FIG. 1(b): A wavefront from a far-field source (rₒ→∞) traced to a target at focal length F=r₁). Snell's law (equivalent here to the conservation of skewness κ for a given ray along its entire trajectory [5, 11])

rn(r)Sin(α)=κ (1)

(where α is the polar angle along the ray), is combined with Fermat's principle of constant optical path length to obtain the governing integral equation

$${\int }_{{r}^{*}}^{1} \frac{κ d r}{r \sqrt{{ρ}^{2} - {κ}^{2}}} = f ( κ ) where ρ ( r ) ≡ rn ( r ) \\ and f ( κ ) = \frac{1}{2} [ {Sin}^{- 1} \frac{κ}{{r}_{0}} + {Sin}^{- 1} \frac{κ}{{r}_{1}} + 2 {Cos}^{- 1} κ ] 0 \leq κ \leq 1. \qquad ( 2 )$$

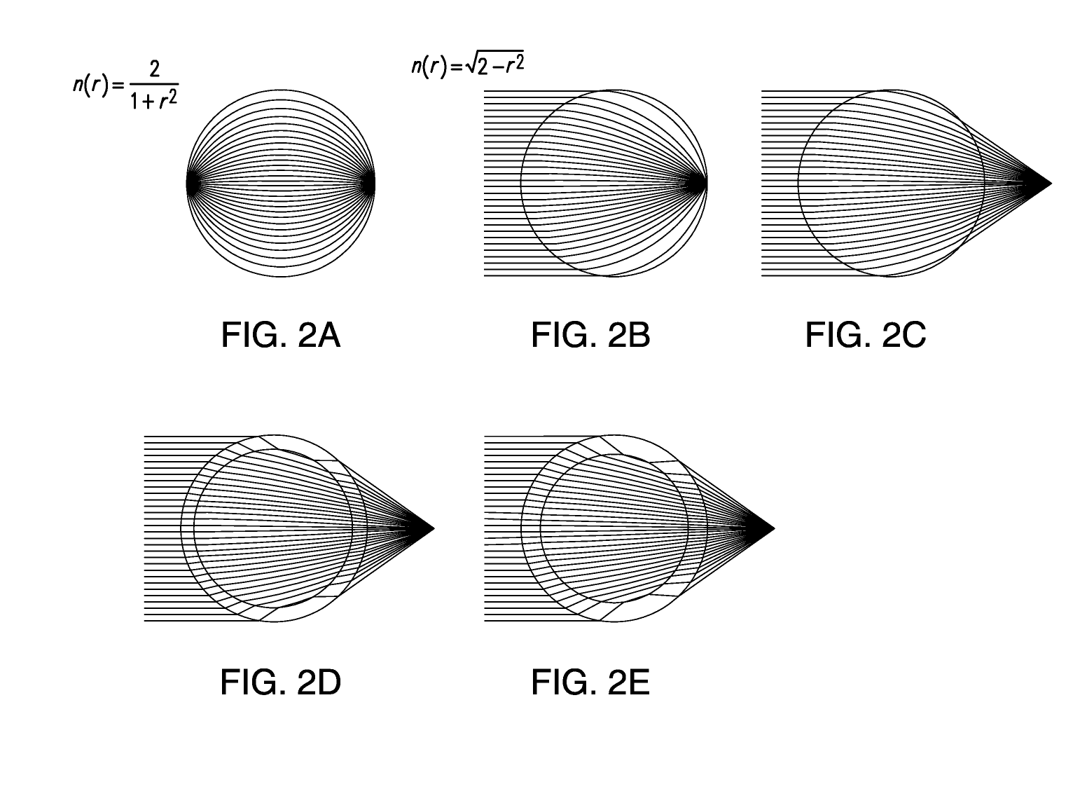

To solve Eq. (2), one multiplies both sides by dκ/√(κ²−ρ²), integrates from ρ to 1, and interchanges the order of integration to obtain:

$$\begin{matrix}{n}_{Luneburg} = exp ( ω ( ρ , {r}_{0} ) + ω ( ρ , {r}_{1} ) ) where ω ( ρ , s ) \\ = \frac{1}{π} {\int }_{ρ}^{1} \frac{{Sin}^{- 1} ( \frac{κ}{s} )}{\sqrt{{κ}^{2} - {ρ}^{2}}} d κ\end{matrix} \qquad ( 3 )$$

where n(r) is assumed to be continuous and invertible, with n(1)=1. The explicit solution cited by Luneburg was for rₒ→∞ and F=1: n(r)=√(2−r²), as shown in FIG. 2(b).

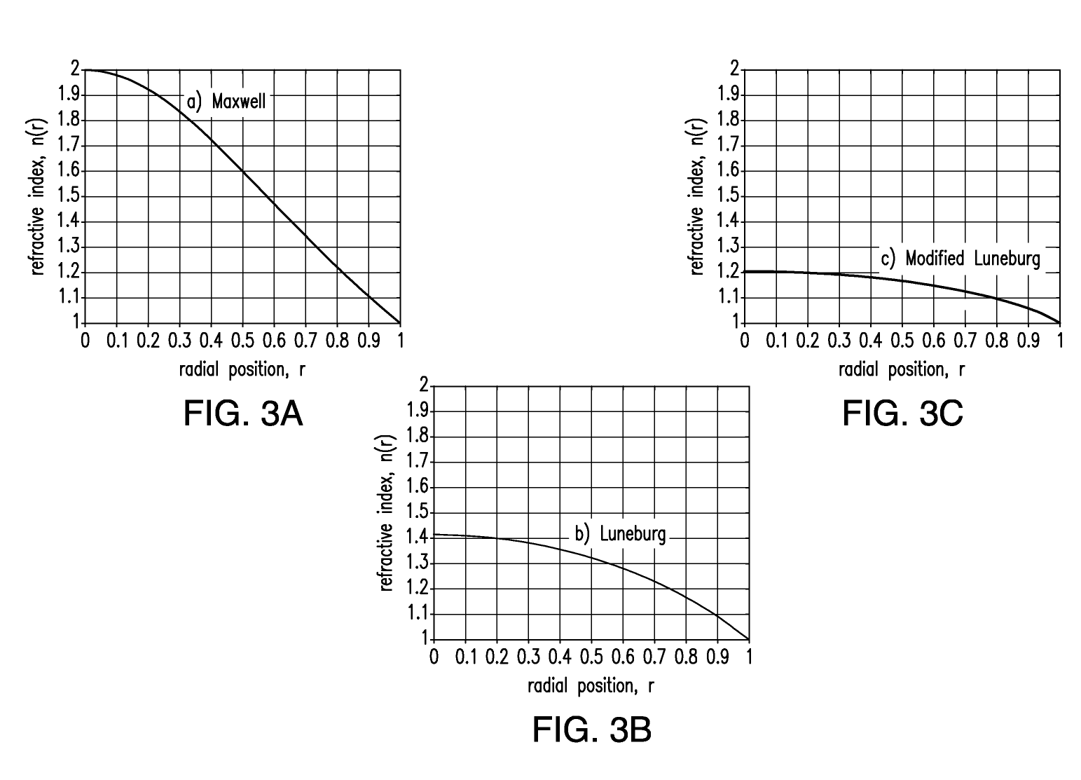

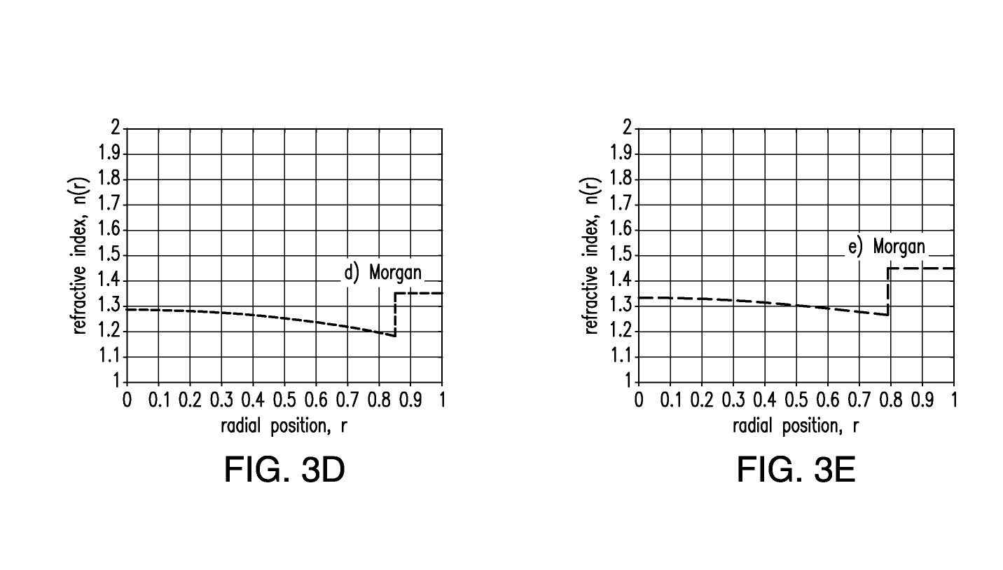

Fletcher [12] generalized the Luneburg's solutions to arbitrary focal length F with strictly numerical (rather than analytic) solutions. As used herein, the focal length of a spherical GRIN lens is the distance from the focus of the lens to the center of the lens sphere, expressed relative to the sphere's unit radius. Morgan [13] demonstrated that introducing a discontinuity in n(r) can relax the first and second constraints. FIG. 2 shows sample raytraces for perfect-imaging spherical GRIN lenses. The refractive index profile n(r) is noted when expressible analytically. (a) Source and focus are diametrically opposite on the sphere's surface (Maxwell [14]). (b) Far-field source to a focus on the sphere's surface (F=1) (Luneburg [1]). (c) Far-field source and arbitrary F [12]. In (a)-(c), the profiles were restricted to continuous functions, and required n(1)=1 as well as sizable Δn. (d)-(e) Morgan [13] demonstrated solutions when a homogeneous exterior shell is permitted (the interior profile is continuous), for arbitrary F, illustrated here for two distinct values of the exterior shell's index and thickness that yield the same F=1.74 as in part (c). FIG. 3 show the n(r) profiles for the lenses in FIG. 2: (a) Maxwell's lens, (b) Luneburg's lens (F=1), (c) a completely continuum-profile lens of F=1.74 based on Fletcher [12]; (d, e) two examples of a F=1.74 lens comprising an outer uniform shell and an inner continuum distribution (calculations based on Morgan [13]) where the minimum n is well above unity and Δn is relatively small.

As noted above, Morgan introduced an extra degree of freedom of an outer shell of constant index n_{constant}, with a continuum interior profile. More generalized Morgan solutions are provided below: Consider the far-field solution with a single discontinuity: a continuum core distribution up to radius a and a uniform outer shell. The governing integral equation of Morgan [13] (Eq. (4)) is:

$$2 {\int }_{{r}^{*} ( κ )}^{1} \frac{κ d r}{r \sqrt{{ρ}^{2} - {κ}^{2}}} = arcsin \frac{κ}{F} + arcsin κ , 0 \leq κ \leq 1 \\ ρ ( r ) = r \cdot n ( r ) \qquad ( 4 )$$

where r* is the smallest radius along that trajectory. The solution for the continuum profile (0≦r≦a) is:

$$n = ( 1 / a ) exp ( ω ( ρ , F ) - Ω ( ρ ) ) where \\ ω ( ρ , F ) = \frac{1}{π} {\int }_{ρ}^{1} \frac{arcsin ( \frac{κ}{F} )}{\sqrt{{κ}^{2} - {ρ}^{2}}} d κ , \\ Ω ( ρ ) = \frac{2}{π} {\int }_{ρ}^{1} \frac{G ( κ )}{\sqrt{{κ}^{2} - {ρ}^{2}}} d κ , \\ G ( κ ) = {\int }_{a}^{1} \frac{κ}{r \sqrt{{ρ}^{2} - {κ}^{2}}} d r \qquad ( 5 )$$

(0≦ρ≦1, F≧1). The integrals in Eq. (5) can be computed numerically. Solutions exist provided Eq. (6) is satisfied:

$$arcsin ( \frac{1}{F} ) \geq 2 {\int }_{a}^{1} \frac{d r}{r \sqrt{{ρ}^{2} - 1}} . \qquad ( 6 )$$

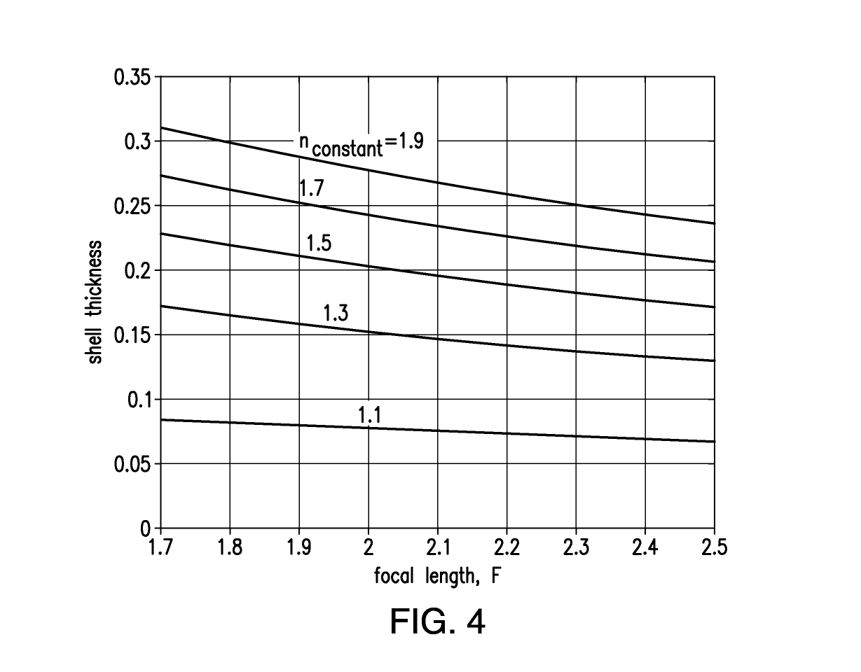

FIG. 4 summarizes how n_{constant} of the outer shell affects that layer's allowed thickness and F. As illustrated, solutions with constant-index shells as suggested by Morgan can significantly raise the minimum refractive index to well above unity, e.g., to values above 1.2, and, simultaneously, reduce Δn from more than 0.4 (for the Luneburg lens) to less than 0.2. Suitable off-the-shelf solar-transparent materials—commonly available plastics and glasses that are also apposite for GRIN lens fabrication processes [3, 15]—typically have refractive indices from ˜1.3 to ˜2, which can be accommodated by the generalized solutions illustrated above. However, the solutions of n(r) above based on Morgan's constant-index shell suggestion only provided a limited solution; there are other more generalized solutions that do not require the constant-index shell which afford more versatile design of the GRIN lens to afford perfect imaging. As will be shown below, perfect imaging can be achieved by, but does not limit to, a single continuum GRIN distribution; rather, it only requires that some finite region of the sphere comprise a continuous gradient index derived to achieve perfect imaging for the lens as a whole. Other regions of the lens can be prescribed or provided by a user, e.g., a core or shells of constant index, or with the refractive index being a specified function of r (linear, or non-linear (e.g., parabolic, logarithmic, polynomial, etc.)). Since the spherical GRIN lens can be fabricated from discrete shells, the lack of continuity poses no problem in lens manufacture [2-4]. In the following, several new classes of solutions of n(r) are provided for perfect imaging spherical GRIN lens design that are amenable to realistic materials and fabrication techniques. Certain exemplary n(r) profiles, herein termed as “champion designs,” illustrate that the solutions provided herein can satisfy the limitations of off-the-shelf polymer technology with feasible scale-up: nₘᵢₙ=1.44 and nₘₐₓ=1.57.

For illustration and not limitation, many of the n(r) profiles described herein are suitable for the cases of practical interest for sunlight—previously deemed unattainable with existing, readily manufacturable, transparent materials. Examples are presented for spherical GRIN lenses that nominally attain perfect imaging because perfect imaging also implies attaining the thermodynamic limit to flux concentration [5, 11]. The latter means that such Luneburg-type solar lenses would constitute single-element concentrators that approach the fundamental maximum for acceptance angle—and for optical tolerance to off-axis orientation—at a prescribed concentration (or vice versa). This also relates to averaged irradiance levels of the order of 10³ now common in concentrator photovoltaics. Moreover, such GRIN lenses offer a unique solution for achieving nominally stationary high-irradiance solar concentration, as will be more fully described below.

In some embodiments of the disclosed subject matter, n(r) of the perfect imaging spherical GRIN lens can accommodate an arbitrary lens surface index N≡n(1). To obtain n(r), Eq. (2) can be rewritten as

$${\int }_{{r}^{*}}^{1} \frac{κ d r}{r \sqrt{{ρ}^{2} - {κ}^{2}}} = \frac{1}{2} ( {Sin}^{- 1} ( \frac{κ}{{r}_{o}} ) + {Sin}^{- 1} ( \frac{κ}{{r}_{1}} ) + 2 {Sin}^{- 1} ( \frac{κ}{N} ) - 2 {Sin}^{- 1} ( κ ) ) \\ 0 \leq κ \leq N \qquad ( 7 )$$

(note the revised domain for κ). The last two terms in Eq. (7) stem from the two extra refractions at the lens surface. Using the substitution d(ln(r))=−dg(ρ)/dr≡−g′(ρ) yields an Abel integral equation:

$$- {\int }_{κ}^{N} \frac{{g}^{′} ( ρ ) κ d r}{\sqrt{{ρ}^{2} - {κ}^{2}}} = \frac{f ( κ )}{2} \\ which has the solution \\ n ( ρ ) = N exp ( \frac{1}{π} {\int }_{ρ}^{N} \frac{f ( κ ) d κ}{r \sqrt{{κ}^{2} - {ρ}^{2}}} ) . \qquad ( 8 )$$

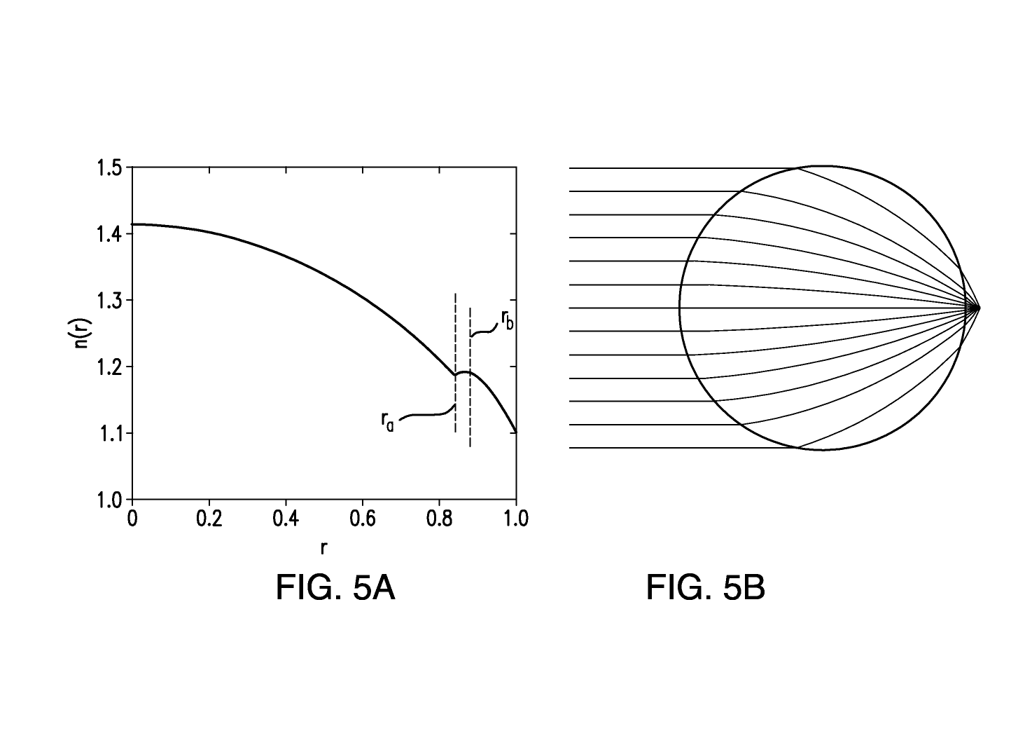

An example of this solution for a lens with N=1.1, F=1.1 and a far-field source is shown in FIG. 5 (FIG. 5(a) shows the solution of the n(r) profile; and 5(b) shows raytraces of several paraxial rays. As illustrated, there exist rₐ and r_{b} in this profile, such that n(0)>n(rₐ), n(r_{b})>n(rₐ), and n(r_{b})>n(1) (also n(0)>n(r_{b}), and n(1)>1). Although the derivations presented here relate to the general near-field problem (arbitrary rₒ and r₁), the illustrative examples pertain to the far-field problem, e.g., relevant to solar concentrator applications.

In some embodiments of the disclosed subject matter, the perfect imaging GRIN lens can have a sizable core of substantially constant refractive index (e.g., made by a homogenous material), whose radius can be ranged in about 0.05 to about 0.95 of the radius of the lens, or about 0.1 to about 0.5 of the radius of the lens, or other sizes as desired or required by the manufacture technology or constraint. Such sizable core of constant refractive index makes it feasible to manufacture the spherical GRIN lens having the precise and robust GRIN profiles as designed to achieve perfect imaging. As used herein, the phrase “substantially constant” as relating to the refractive index of a portion of the GRIN lens (e.g., a “constant-index core” or a “constant-index shell”) means that the variation of the refractive index in the defined range of r of the portion does not exceed 0.001. In certain embodiments, the variation of refractive index can be smaller, e.g., smaller than 10⁻⁴.

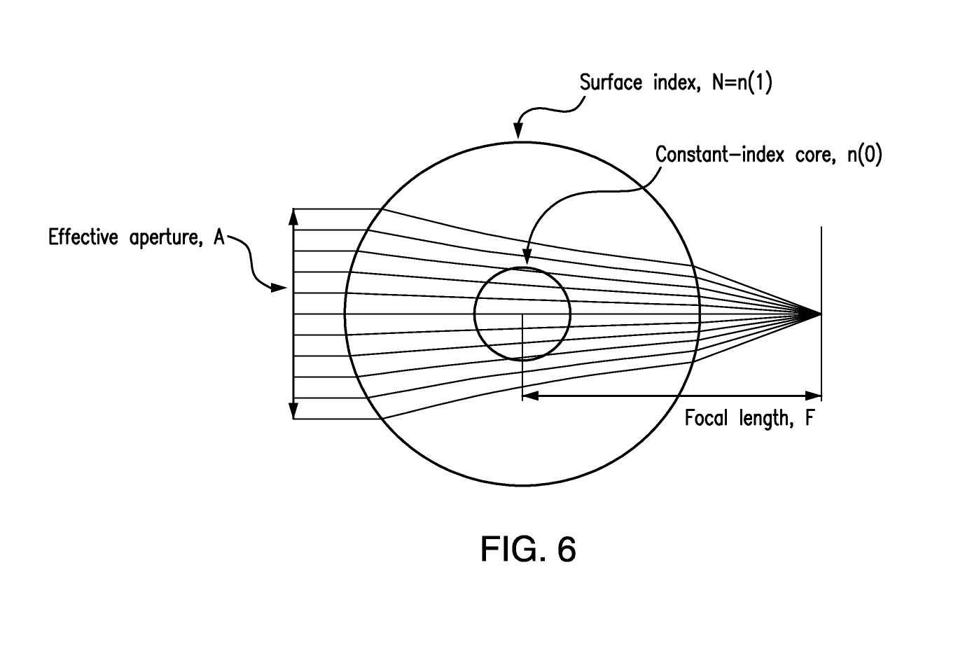

As disclosed herein, the n(r) profile having a constant-index core region can be obtained as follows. With the boundary condition n(1), a value for the effective aperture A is selected, along with the desired values of F and n(0), as shown in FIG. 6. As used herein, the aperture of a spherical GRIN lens refers to the cross-section diameter of the active irradiation surface (the portion of the sphere surface for receiving the incidence light) divided by the diameter of the lens sphere. Both full aperture (A=1) and non-full aperture (A<1) can be used as the input herein. Although non-full aperture was explored by Sochacki [16] in investigation of Luneburg-type lenses, Sochacki's requirement that n(r) be a smooth function and his narrow parameter space that excluded full-aperture lenses severely restricted the available solutions.

Given the input parameters, the governing equation becomes:

$${\int }_{N}^{κ} \frac{{κg}^{′} ( ρ ) d ρ}{\sqrt{{ρ}^{2} - {κ}^{2}}} = \{ \begin{matrix}\frac{{f}_{1} ( κ )}{2} & 0 \leq κ \leq A \\ \frac{{f}_{1}^{+} ( κ )}{2} & A \leq κ \leq N\end{matrix} \\ where \\ {f}_{1} ( κ ) = {Sin}^{- 1} ( \frac{κ}{{r}_{o}} ) + {Sin}^{- 1} ( \frac{κ}{{r}_{1}} ) + 2 {Sin}^{- 1} ( \frac{κ}{N} ) - 2 {Sin}^{- 1} ( κ ) \qquad ( 9 )$$

and ƒ₁⁺(κ) remains to be determined in the analysis that follows.

As before, the solution follows from multiplying both sides by dκ/√(κ²−ρ²), integrating from ρ to N, and interchanging the order of integration:

$$\begin{matrix}n ( ρ ) = N exp [ \frac{1}{π} {\int }_{ρ}^{A} \frac{{f}_{1} ( κ )}{\sqrt{{κ}^{2} - {ρ}^{2}}} d κ + \frac{1}{π} {\int }_{A}^{N} \frac{{f}_{1}^{+} ( κ )}{\sqrt{{κ}^{2} - {ρ}^{2}}} d κ ] \\ = \{ \begin{matrix}N exp [ ω ( ρ , {r}_{1} , A ) + ω ( ρ , {r}_{0} , A ) + 2 ω ( ρ , N , A ) - 2 ω ( ρ , 1 , A ) + \frac{1}{π} {\int }_{A}^{N} \frac{{f}_{1}^{+} ( κ )}{\sqrt{{κ}^{2} - {ρ}^{2}}} d κ ] & 0 \leq ρ \leq A \\ N exp [ \frac{1}{π} {\int }_{ρ}^{N} \frac{{f}_{1}^{+} ( κ )}{\sqrt{{κ}^{2} - {ρ}^{2}}} d κ ] & A \leq ρ \leq N .\end{matrix}\end{matrix} \qquad ( 10 )$$

Eq. (10) can be recast as

$$ln ( \frac{n ( ρ )}{N} ) = \frac{1}{π} {\int }_{ρ}^{A} \frac{{f}_{1} ( κ )}{\sqrt{{κ}^{2} - {ρ}^{2}}} d κ + \frac{1}{π} {\int }_{A}^{N} \frac{{f}_{1}^{+} ( κ )}{\sqrt{{κ}^{2} - {ρ}^{2}}} d κ , \\ and , rearranging \text{:} \\ \begin{matrix}\frac{1}{π} {\int }_{A}^{N} \frac{{f}_{1}^{+} ( κ )}{\sqrt{{κ}^{2} - {ρ}^{2}}} d κ = ln ( \frac{n ( ρ )}{N} ) - \frac{1}{π} {\int }_{ρ}^{A} \frac{{f}_{1} ( κ )}{\sqrt{{κ}^{2} - {ρ}^{2}}} d κ \\ = ln ( \frac{n ( ρ )}{N} ) - ω ( ρ , {r}_{1} , A ) + ω ( ρ , {r}_{0} , A ) + \\ 2 ω ( ρ , N , A ) - 2 ω ( ρ , 1 , A )\end{matrix} \\ where \\ ω ( ρ , A , s ) = \frac{1}{π} {\int }_{ρ}^{s} \frac{{Sin}^{- 1} ( \frac{κ}{A} )}{\sqrt{{κ}^{2} - {ρ}^{2}}} d κ \qquad ( 11 )$$

and n(p) is constant for the range 0≦ρ≦ρₒ (the constant-index core) where ρₒ≦A.

Hence, one needs to solve an integral equation with constant limits of integration, known as a Fredholm integral equation of the first kind. Solutions are difficult to find because such integral equations are commonly ill-posed and singular [17, 18]. Before invoking methods that might yield a closed-form solution [19], Eq. (11) can be solved numerically. One starts by assuming the solution can be represented as

$${f}_{1}^{+} ( κ ) = {\sum }_{i} {w}_{i} {ϕ}_{i} ( κ ) . \qquad ( 12 )$$

(In the examples here, Lagrange polynomials are employed, but the selection can be expanded to other representations.) Substitution of Eq. (12) into Eq. (11) yields

$$\begin{matrix}\frac{1}{π} {\int }_{A}^{N} \frac{{f}_{1}^{+} ( κ )}{\sqrt{{κ}^{2} - {ρ}^{2}}} d κ = \frac{1}{π} {\int }_{A}^{N} \frac{{\sum }_{i} {w}_{i} {ϕ}_{i} ( κ )}{\sqrt{{κ}^{2} - {ρ}^{2}}} d κ \\ = \frac{1}{π} {\sum }_{i} {w}_{i} {\int }_{A}^{N} \frac{{ϕ}_{i} ( κ )}{\sqrt{{κ}^{2} - {ρ}^{2}}} d κ .\end{matrix} \qquad ( 13 )$$

Upon proper discretization of the domain of κ, Eq. (13) becomes a system of linear equations:

Bw=g (14)

where the unknowns are the weights wᵢ in Eq. (12).

As noted by Twomey [20], Phillips [21] demonstrated that the exact solution obtained when Bw=g is solved is almost always poor and often disastrously so—in the sense that the solution oscillates or displays some other feature which conflicts with a priori knowledge. Accordingly, the numerical techniques suggested by Twomey and Phillips can be adopted here, with the solution given by

w(B*B+βH)⁻¹B*g (15)

where * denotes matrix transposition, β is an arbitrary number usually in the range 0 to 1, and the matrix H can have various representations [20]. Examples with smooth (non-oscillating) solutions can be presented by following Phillips' procedure (and hence H matrix):

$$H = [ \begin{matrix}1 & - 2 & 1 & 0 & 0 & … & … & … \\ - 2 & 5 & - 4 & 1 & 0 & … & … & … \\ 1 & - 4 & 6 & - 4 & 1 & 0 & … & … \\ 0 & 1 & - 4 & 6 & - 4 & 1 & 0 & … \\ … & … & … & … & … & … & … & … \\ … & … & 0 & 1 & - 4 & 6 & - 4 & 1 \\ … & … & … & 0 & 1 & - 4 & 5 & - 2 \\ … & … & … & 0 & 0 & 1 & - 2 & 1\end{matrix} ] . \qquad ( 16 )$$

Only physically inadmissible solutions are rejected, e.g., multi-valued functions with more than one value of n(r) for a given value of r.

The derivation required for a third-order Lagrange polynomial is presented herein, but the technique can be expanded to any order polynomial approximation or alternative interpolation technique (splines, Hermite polynomials, etc.) [22]:

$${f}_{1}^{+} ( κ ) = \frac{κ - {κ}_{i + 1}}{{κ}_{i} - {κ}_{i + 1}} \frac{κ - {κ}_{i + 2}}{{κ}_{i} - {κ}_{i - 2}} \frac{κ - {κ}_{i + 3}}{{κ}_{i} - {κ}_{i + 3}} {w}_{i} + \frac{κ - {κ}_{i}}{{κ}_{i + 1} - {κ}_{i}} \frac{κ - {κ}_{i + 2}}{{κ}_{i + 1} - {κ}_{i + 2}} \frac{κ - {κ}_{i + 3}}{{κ}_{i + 1} - {κ}_{i + 3}} {w}_{i + 1} + \frac{κ - {κ}_{i}}{{κ}_{i + 2} - {κ}_{i}} \frac{κ - {κ}_{i + 1}}{{κ}_{i + 2} - {κ}_{i + 1}} \frac{κ - {κ}_{i + 3}}{{κ}_{i + 2} - {κ}_{i + 3}} {w}_{i + 2} + \frac{κ - {κ}_{i}}{{κ}_{i + 3} - {κ}_{i}} \frac{κ - {κ}_{i + 1}}{{κ}_{i + 3} - {κ}_{i + 1}} \frac{κ - {κ}_{i + 2}}{{κ}_{i + 3} - {κ}_{i + 2}} {w}_{i + 3} . \qquad ( 17 )$$

Equation (17) is inserted into Eq. (13) and integrated over κ. A proper discretization of the free variable ρ and the dummy variable κ results in an algebraic system of equations in the form of Eq. (14) from which one then retrieves the factors wᵢ, as well as ƒ₁⁺(κ) through Eq. (12). Finally, inserting ƒ₁⁺(κ) into Eq. (10), a smooth n(r) is obtained. Alternatively, the matrix B can be directly inverted (actually, pseudo-inverted due to its poor rank) to obtain oscillatory solutions. Then, with Luneburg's basic integral equation transformation [1], one emerges with the corresponding n(r).

The solutions for the constant-index core are not exactly constant, but rather oscillate with a magnitude of order 10⁻⁵ to 10⁻³ around the nominally constant n(0). Raytracing verifies that the solutions for the core can basically be treated as constant values. Finally, observing that the solution in Eq. (10) is everywhere continuous implies ƒ₁⁺(B)=ƒ₁(B)—a condition that needs to be implemented in the solution of Eqs. (14)-(15). Note that the actual n(0) and the core's radial extent emerge as part of the solution. Namely, an initial guess of n(0) can serve as an input parameter, but the solution can iterate to a different final value.

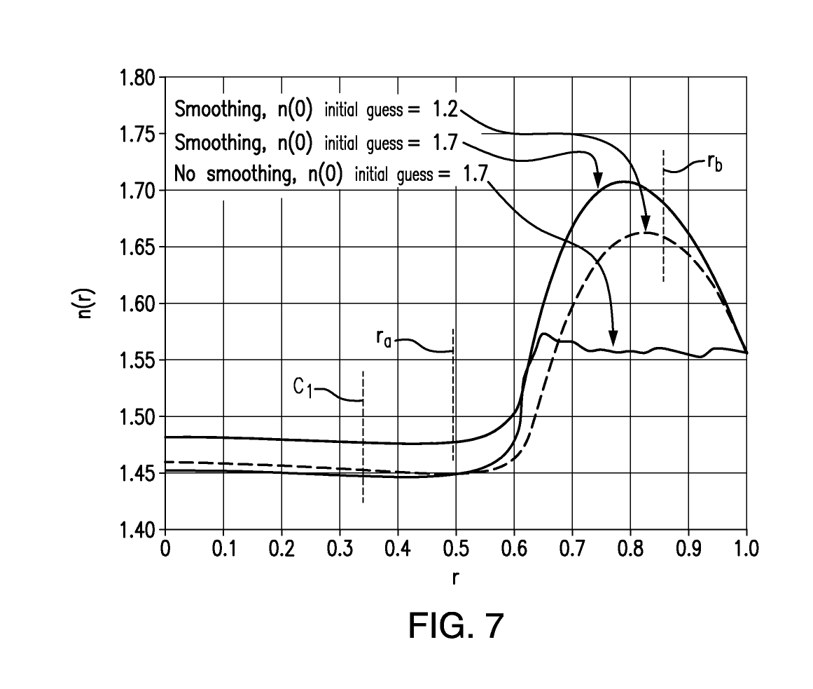

In the following, an exemplary spherical GRIN lens having an extensive constant-index core and a prescribed surface index is obtained. The aim here is to achieve a constant-index core that comprises a substantial fraction of the lens radius, with a given surface index N=1.555, A=0.97, F=1.71 and ρₒ=0.12 (with grid linear partitions of 18 nodes for κ, 15 nodes for ρ, and β=1). Three distinct solutions for the same input parameters are shown in FIG. 7, which shows the influence of (a) the initial guess for n(0), and (b) the smoothed vs. oscillatory calculational procedure. The solution based on the pseudo-inverse of the matrix B in Eq. (14) exhibits oscillatory behavior that would render lens fabrication problematic (the other two solutions were generated with the smoothing technique depicted above), but has the advantage of admitting a lower Δn (low enough, in fact, to qualify as a champion design). All three profiles yield the same perfect imaging. As illustrated, there exist rₐ and r_{b} in the top profile (as well as in the other 2 profiles), such that n(0)>n(rₐ), n(r_{b})>n(rₐ), and n(r_{b})>n(1) (also n(0)<n(r_{b}), and n(1)>1). Further, there exist C₁ as shown, such that when 0≦r≦C₁, the refractive index is substantially constant.

In the following example, a spherical GRIN lens having a constant index in both the core and the outer layer is provided. Inspection of Eq. (10) reveals that if ƒ₁⁺(κ)=const, then n(ρ)=const for A₂≦ρ≦N. Hence, imposing this condition in the numerical solution presented previously can yield solutions with both a constant-index core and a constant-index outer layer. The governing equation is rewritten as

$${\int }_{N}^{κ} \frac{{κg}^{′} ( ρ ) d ρ}{\sqrt{{ρ}^{2} - {κ}^{2}}} = \{ \begin{matrix}\frac{{f}_{1} ( κ )}{2} & 0 \leq κ \leq {A}_{1} \\ \frac{{f}_{1}^{+} ( κ )}{2} & {A}_{1} \leq κ \leq {A}_{2} \\ \frac{{f}_{2}^{+} ( κ )}{2} & {A}_{2} \leq κ \leq N\end{matrix} \qquad ( 18 )$$

where the function ƒ₁⁺(κ) is determined as part of the solution, and the function ƒ₂⁺(κ) follows from the prescribed outer shell (e.g., for a constant-index shell, ƒ₂⁺(κ)=0, which yields n(ρ)=N for A₂≦ρ≦N). Eq. (18) is solved by

$$n ( ρ ) = \{ \begin{matrix}N exp [ ω ( ρ , {r}_{1} , {A}_{1} ) + ω ( ρ , {r}_{0} , {A}_{1} ) + 2 ω ( ρ , N , {A}_{1} ) - 2 ω ( ρ , 1 , {A}_{1} ) + {\int }_{{A}_{1}}^{{A}_{2}} \frac{{f}_{1}^{+} ( κ )}{π \sqrt{{κ}^{2} - {ρ}^{2}}} d κ + {\int }_{{A}_{2}}^{N} \frac{{f}_{2}^{+} ( κ )}{π \sqrt{{κ}^{2} - {ρ}^{2}}} d κ ] & 0 \leq ρ \leq {A}_{1} \\ N exp [ {\int }_{ρ}^{{A}_{2}} \frac{{f}_{1}^{+} ( κ )}{π \sqrt{{κ}^{2} - {ρ}^{2}}} d κ + {\int }_{{A}_{2}}^{N} \frac{{f}_{2}^{+} ( κ )}{π \sqrt{{κ}^{2} - {ρ}^{2}}} d κ ] & {A}_{1} \leq ρ \leq {A}_{2} \\ N exp [ {\int }_{ρ}^{N} \frac{{f}_{2}^{+} ( κ )}{π \sqrt{{κ}^{2} - {ρ}^{2}}} d κ ] & {A}_{2} \leq ρ \leq N\end{matrix} \qquad ( 19 )$$

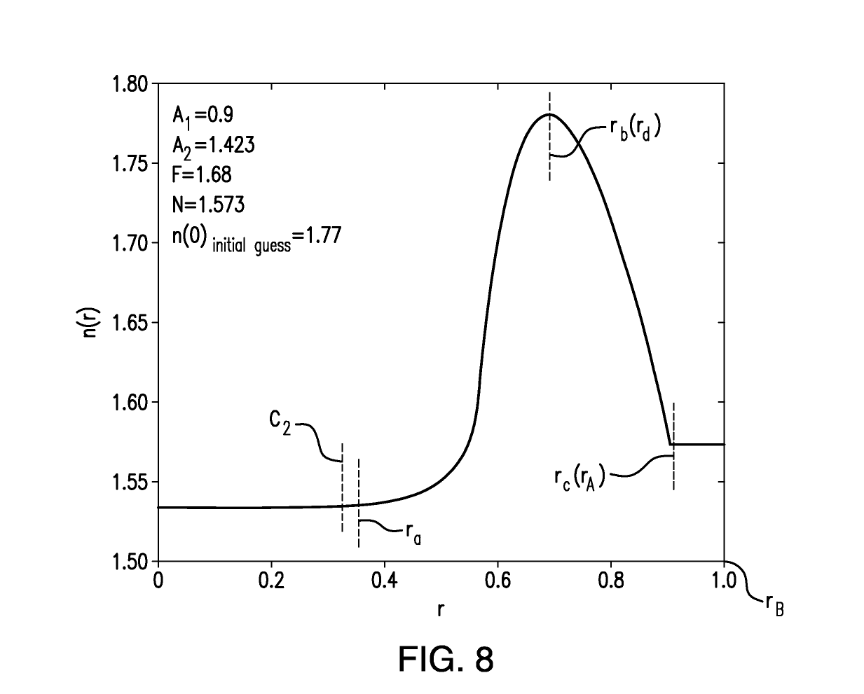

and the resulting n(r) is illustrated in FIG. 8 (which depicts n(r) for a lens that include a constant-index outer shell and a substantially constant index core. Lens input parameters are F=1.680, A₁=0.900, A₂=1.423 and N=1.573. This solution (based on the smoothing calculational method described above) has n(0)=1.534 extending over a core radius of 0.33). As illustrated in FIG. 8, there exist rₐ and r_{b} in the profile, such that n(0)>n(rₐ), n(r_{b})>n(rₐ), and n(r_{b})>n(1) (also n(0)<n(r_{b}), and n(1)>1). Further, there exists C₂ as shown, such that when 0≦r≦C₂, the refractive index is substantially constant (and there also exists rd, C₂<r_{d}<1, and n(r_{d})>n(C₂)). In addition, this profile also includes r_{c}, for r_{c}<r<1 (i.e., r_{A}<r<r_{B} in this particular case), the refractive index is constant (predefined).

The Fredholm Eq. (11) possesses a closed-form solution. Applying the transformation

$$z = {ρ}^{2} , \\ t = {κ}^{2} , \\ γ ( t ) = \frac{{f}^{+} ( κ )}{\sqrt{κ}} , \\ F ( z ) = 2 ϕ ( \sqrt{z} ) \\ where \\ ϕ ( ρ ) = log ( \frac{n ( ρ )}{N} ) - ω ( ρ , {r}_{1} , A ) + ω ( ρ , {r}_{0} , A ) + 2 ω ( ρ , N , A ) - 2 ω ( ρ , 1 , A ) , \qquad ( 20 )$$

Eq. (11) becomes a singular integral equation

$${\int }_{{A}_{1}}^{{N}_{1}} \frac{γ ( τ )}{\sqrt{τ - z}} d τ = π F ( z ) , \\ where \\ {A}_{1} = {A}^{2} , \\ {N}_{1} = {N}^{2} \qquad ( 21 )$$

for which the closed-form solution is

$$γ ( t ) = - \frac{1}{2 π} \sqrt{\frac{{N}_{1} - t}{t - {A}_{1}}} {\int }_{{A}_{1}}^{{N}_{1}} \sqrt{\frac{{N}_{1} - s}{s - {A}_{1}}} \frac{d}{d s} [ {\int }_{{A}_{1}}^{s} \frac{F ( u )}{\sqrt{s - u}} d u ] d s + \frac{1}{2} \frac{d}{d t} {\int }_{{A}_{1}}^{t} \frac{F ( u )}{\sqrt{s - u}} d s . \qquad ( 22 )$$

γ(κ) is then found by numerically by evaluating the derivatives and integrals in Eq. (22). The singularities that appear in the evaluation of the integral can be treated numerically with Matlab's quadgk function [23].

An extra condition is needed to produce smooth solutions:

$${f}^{+} ( A ) = {Sin}^{- 1} ( \frac{A}{{r}_{o}} ) + {Sin}^{- 1} ( \frac{A}{{r}_{1}} ) + 2 {Sin}^{- 1} ( \frac{A}{N} ) - 2 {Sin}^{- 1} ( A ) . \qquad ( 23 )$$

In the discretized calculational grid, the first two values of ƒ⁺ might need to be equated to ƒ⁺(A), or a similar heuristic scheme can be found to produce a solution that is smooth and physically admissible.

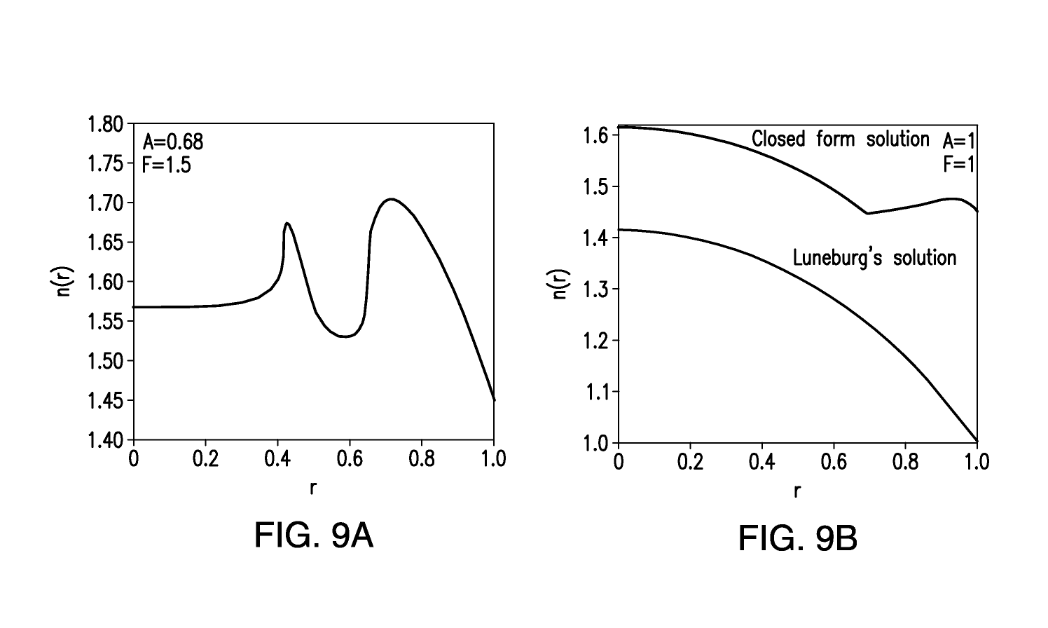

Using the closed-form approach, a sample solution for a far-field source, F=1.5 and A=0.75 is obtained with a constant-index core up to r=0.3, which is graphed in FIG. 9a. If one requires a full effective aperture A→1, then N needs to be raised substantially (N≧2) in order to maintain a constant-index core. Although the full-aperture solutions generated with this technique exhibit both a considerably higher nₘᵢₙ and a lower Δn than the original Luneburg method (FIG. 9b), they need a coarse discretization in evaluating the integrals in Eq. (22). For this specific example, a 3-point equal-spacing discretization was used in the numerical integrations.

The new classes of GRIN solutions point to an infinite number of previously unidentified solutions that can now realistically be implemented for optical frequencies. Currently available techniques and materials can be used to fabricate the spherical GRIN lens having the n(r) profiles provided herein. For example, polymeric or glass materials can be used to fabricate the GRIN lenses; the refractive index of the materials can be in the range of 1.1 to 2.0, with variation of the refractive index across the lens being less than 0.3, or even smaller (e.g., smaller than 0.13). The methods for manufacturing GRIN lenses as disclosed in U.S. Pat. Nos. 6,582,807 and 7,002,754 (as well as references [2-4]) can be used; the disclosures of these patents are incorporated herein by reference in their entireties. The progressive refractive index profile of the fine-layered structure of the spherical GRIN lens manufactured based on these techniques can sufficiently approximate the continuous n(r) as provided such that the GRIN lens can produce perfect imaging.

Further, the flexibility of accommodating ranges of refractive index previously viewed as intractable based on existing GRIN optical analyses can also open new vistas in infrared imaging and concentration at such time as manufacturable materials become available.

In another aspect, the disclosed subject matter utilizes spherical GRIN lens and/or perfect imaging to provide workable solution to the nominally stationary CPV system. Perfect imaging is an instance where imaging and nonimaging objectives coalesce because perfect imaging is non-trivially synonymous with attaining the fundamental limit to concentration [5, 11]. Recognizing that perfect imaging cannot be realized with a finite number of optical elements, and that an optic comprising many reflectors is impractical, the disclosed subject matter utilizes GRIN lens as the optic partly due to the fact that its refractive index distribution is a nominal continuum. Further, the disclosed subject matter provides GRIN lenses for nominally stationary solar concentrators that are amenable to realistic materials and fabrication technologies.

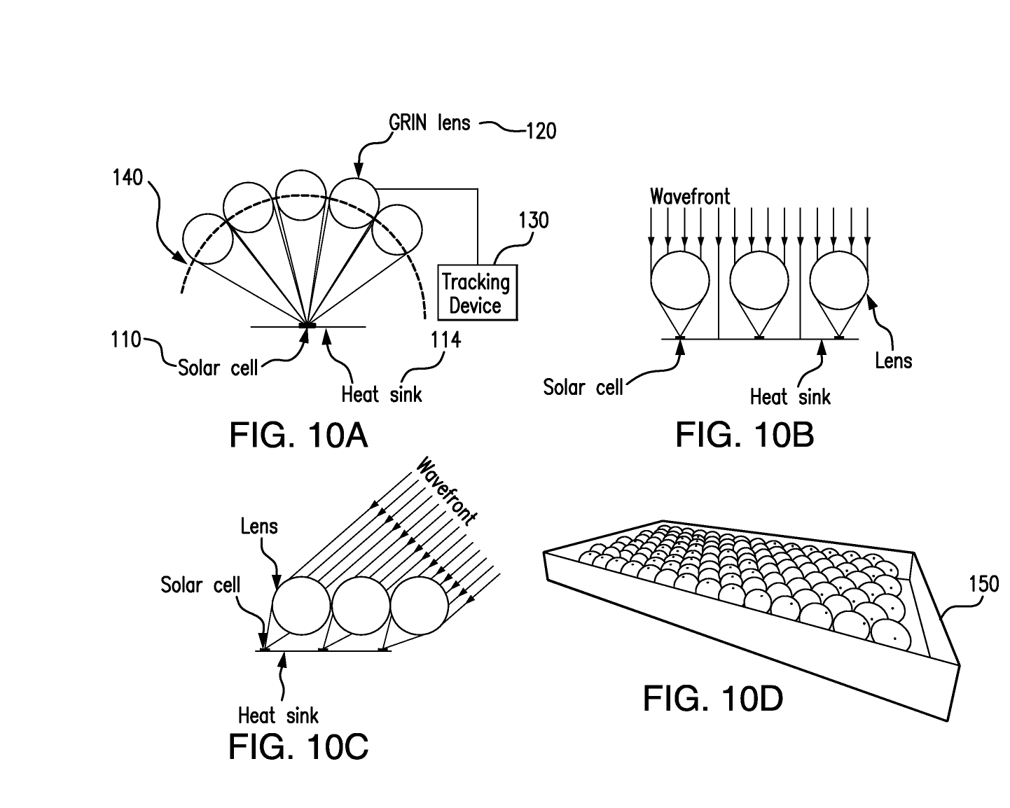

In reference to FIG. 10a (which is drawn not to scale and for illustration purpose only), the disclosed subject matter provides a system for photovoltaic solar concentration, which includes: a stationary absorber, e.g., a photovoltaic cell (e.g., solar cell) 110, a spherical gradient index (GRIN) lens 120 as the optic, wherein the photovoltaic cell is placed at a distance from the center of the GRIN lens, the distance being equal to the focal length of the GRIN lens for the sun, and a tracking device 130 operatively coupled to the GRIN lens, the tracking device capable of moving the GRIN lens along the surface of a virtual sphere 140 to track the trajectory of the sun (not shown) while maintaining the distance. An associated method of utilizing solar energy is also provided, which includes placing a photovoltaic cell at the focal length of a spherical GRIN lens, and moving the GRIN lens to track the trajectory of the sun while maintaining the distance. During moving the GRIN lens, the photovoltaic cell is kept stationary.

As illustrated in FIG. 10a, the system can further include a backing plate 114 (which can serve as, or includes a heat sink) have a surface to which and the photovoltaic cell is affixed (e.g., thermally bonded). As illustrated in FIG. 10d, a plurality of GRIN lens, along with the backing plate and the tracking device(s), can be enclosed in a housing 150, e.g., hermetically, to form a nominally stationary module (that is, only the optic is moved by the tracking device to track the sun, while the module as a whole remains stationary). The nominal stationarity of the module can result in an ostensible loss in collectible energy of ˜30% (annual average, clear climate, mid-latitude) because either spacing the lenses results in uncollected radiation (as shown in FIG. 10b), or the lenses are closely packed and incur mutual shading (as shown in FIG. 10c). However, the loss of collectible energy would not pose a significant challenge for the practicality or usefulness of the system, as will be further discussed below.

In the photovoltaic system, the size of the GRIN lens can be selected according to practical requirement, such as the desired dimension of the solar module, the packing density of the GRIN lens, as well as the size of the solar cell used. As will be further discussed below, the geometric concentration C of the system (the ratio between the squared diameter of the GRIN lens and that of the solar cell) can be selected up to about 30000. However, to provide compromise between solar concentration and misalignment tolerance and due to other practical considerations, the geometric concentration can be selected between 1000 and 2000. For example, at geometric concentration C≈1300, for a 1 mm diameter solar cell, the GRIN lens can be about 36 mm in diameter. Commercially available accuracy microtrackers can be used as the tracking device.

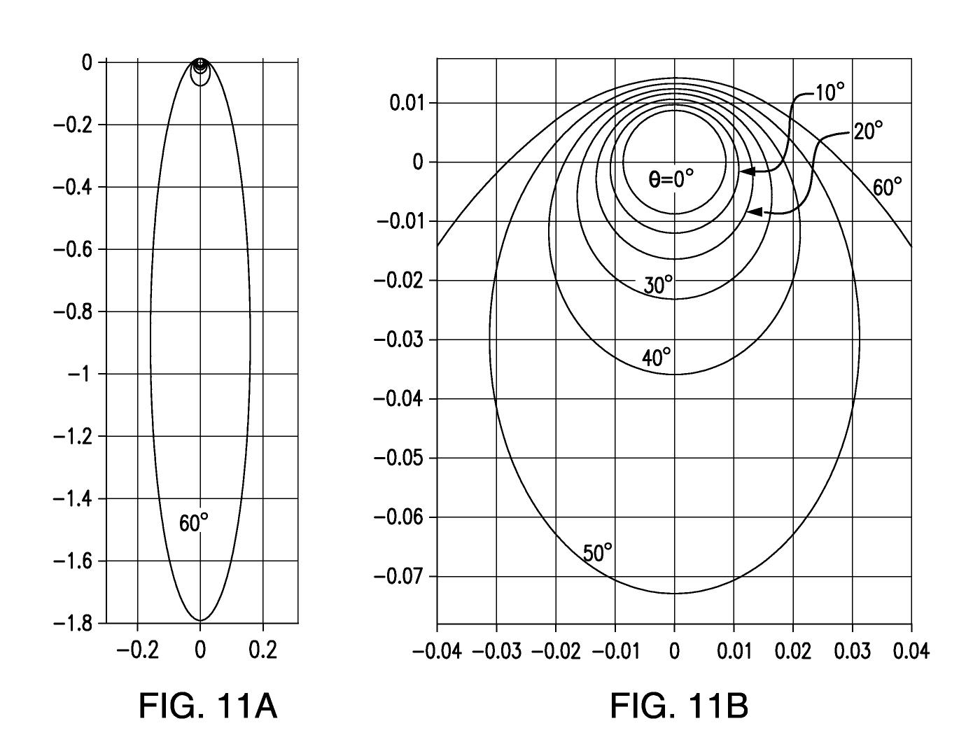

As the solar cell of the system remains stationary while the GRIN lens is moved, the focal spot does not remain circular, but changes with incidence angle. The focal spot projected onto the cell can vary from a minimal disc at normal incidence to an elliptical area that increases with solar incidence angle, as illustrated in FIG. 11. FIG. 11(a) depicts focal spot on the static planar absorber at incidence angles 0 from 0 to 60° (˜8 hr/day of solar beam collection) illustrated for F=1.74; FIG. 11(b) shows enlargement restricted to θ=0-50°. Substantial power density dilution is required only at the very largest incidence angles. θ_{acc}=5 mrad. Such variation of the focal spot projection engenders a tradeoff between collection efficiency and concentration. For given F and θ_{acc}, these results are independent of the particular n(r) because they all yield the same imaging properties. (The target flux maps are non-uniform, but the inhomogeneities are of minor consequence for current concentrator cells, as elaborated below.)

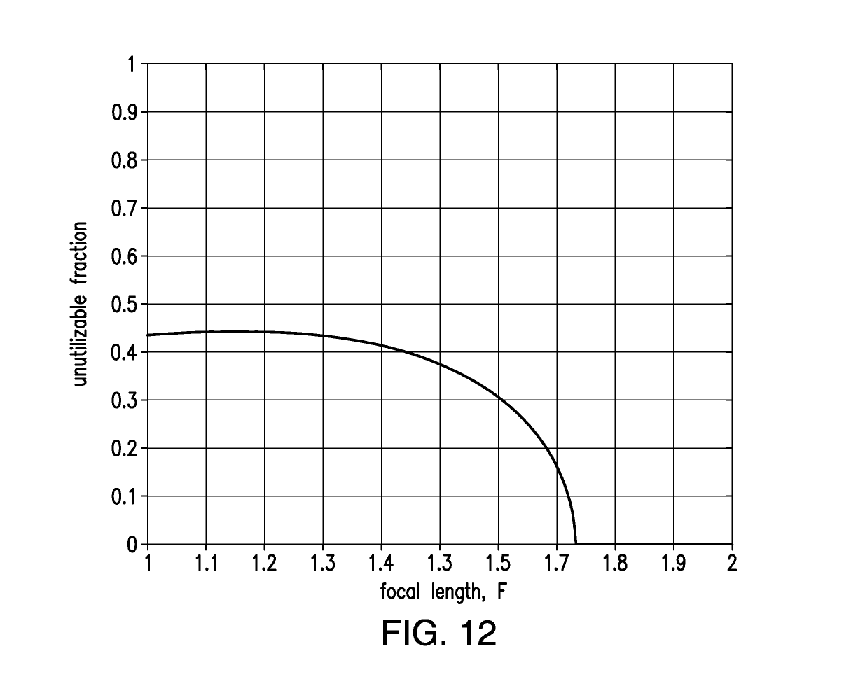

The collection efficiency also depends on F. At short F, a sizable fraction of collectible radiation strikes the underside of the absorber and hence is unutilizable. Completely avoiding this loss requires F≧√3 (see FIG. 12). (F values of at least ˜1.74 are also needed in order to avoid the lens trajectory not intersecting the static plane of the absorber). Thus, in certain embodiments, the focal length of the GRIN lens is selected to be greater than 1.73.

Although the stationary high-concentration modules described herein can incur loss in the averaged incidence angle cosine, eliminating massive precision tracking of large arrays in favor of precision cm-scale lens tracking inside the modules makes the stationary system valuable and opens the possibility of rooftop CPV.

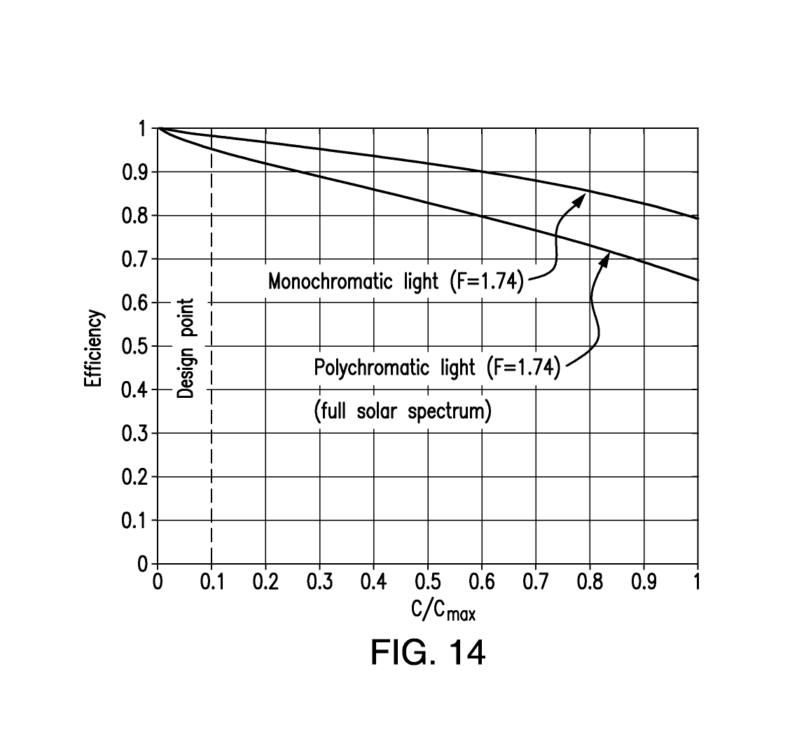

Daylong collection was evaluated by averaging over incidence angles from 0 to 60°, with the largest value—corresponding to ˜8 hr/day of collection—chosen based on considerations of excessive mutual shading inside the module. (The solar input was also energy-weighted at each incidence angle and averaged over the year, based on typical clear-day mid-latitude solar beam radiation, and found negligible changes relative to taking the simple time-weighted average.) Lens design and performance evaluation are based on monochromatic radiation at mid-spectrum. Representative dispersion losses (somewhat case-specific based on the materials chosen for lens fabrication) are quantified as shown in FIG. 14.

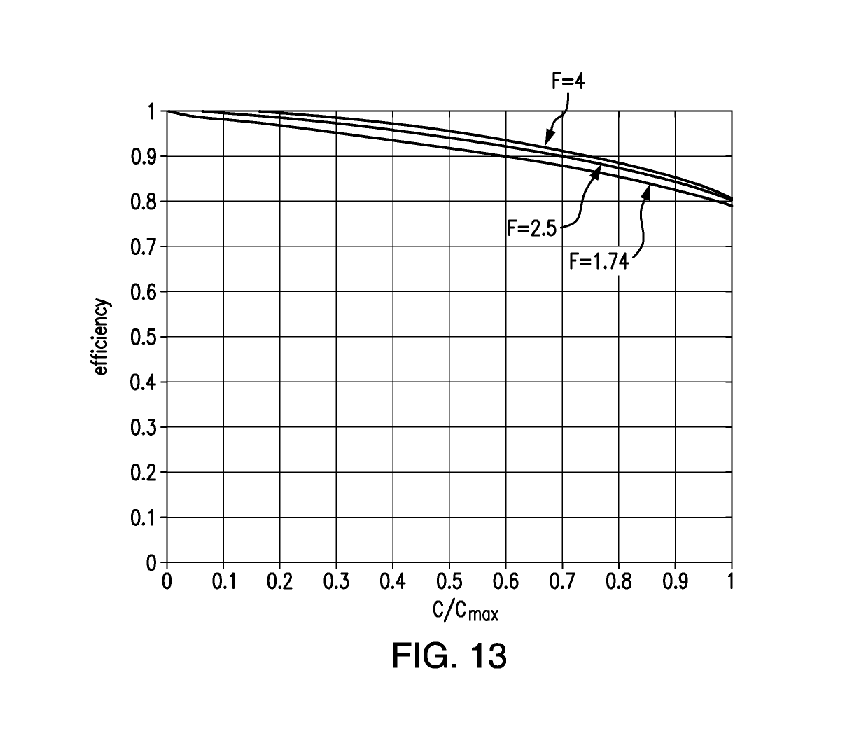

Characteristic curves of collection efficiency versus geometric concentration C (relative to Cₘₐₓ) were generated by raytrace simulation for a range of F. (Collection efficiency here omits Fresnel reflections and absorption, for the lens and module cover glazing, which are readily quantified, and depend on whether anti-reflective coatings are applied.) θ_{acc}=5 mrad was adopted, based on its being achievable in miniaturized solar concentrators [24]. (θ_{acc}=7 mrad has been realized in large-scale CPV systems with massive dual-axis trackers [8].) The plots in FIG. 13 (showing the dependence of the efficiency-concentration characteristic on F) were also found to be insensitive to θ_{acc} as large as 10 mrad (provided the abscissa remains relative concentration C/Cₘₐₓ), which effectively incorporates non-negligible random errors in the thickness and exact refractive index of the spherical shells in the GRIN lens.

To gauge realistic design conditions and to evaluate CPV optical performance, it is first noted that today's concentrator cells exhibit efficiencies that peak at irradiance values not exceeding ˜10³ suns [7, 25-29]. At θ_{acc}=5 mrad and F=1.74, Cₘₐₓ≈13,000, so C=1,300 corresponds to C/Cₘₐₓ=0.1. The geometric collection efficiency is then 98% (FIG. 13). In addition, achieving substantial optical tolerance to off-axis orientation (e.g., a tolerance half-angle θₜ>1°) mandates designing for θ_{acc} well below θₜ, which in turn means C/Cₘₐₓ values substantially below unity [30].

Concentration can be increased to ˜4,000 (conceivably germane for future ultra-efficient ultra-small solar cells) at only 5% ray rejection. Even in the extreme case of θ_{acc}=10 mrad (so that C=1,300 corresponds to C/Cₘₐₓ≈0.4), the geometric losses are only 7%. The results summarized in FIG. 13 allow the estimation of collection efficiency for essentially all concentration values of interest, and sharpen the high-collection potential of spherical GRIN lenses even in the nominally stationary strategy portrayed here.

As an example of the key dimensions becoming viable when commercial miniature cells are used, consider cell and lens diameters of 1 and 36 mm, respectively (C=1,300) in a square 2.5 m² module ˜65-70 mm deep (glazing, heat sink and internal micro-tracker included). The internal lens tracking requires a clearance of ˜1.5 lens radii: a dead space of ˜27 mm on each edge of the module's periphery, corresponding to ˜3% of the module's gross area (in addition to the packing loss of ˜11% for spheres in a plane). The lenses (polymeric layers of density ˜1 g/cm³ [3, 15]), would then comprise a mass of ˜15 kg per m² of module aperture (to which an extruded aluminum micro-tracker assembly would add ˜5 kg).

Chromatic aberration (dispersion loss) was evaluated using an AM1.5D solar spectrum and a Cauchy-type dispersion relation based on the measured properties of representative materials [31]—plotted in FIG. 14 (showing quantifying dispersion losses, where efficiency-concentration curves were generated based on the nominally monochromatic wavelength used for designing the lens, and then based on the AM1.5D solar spectrum. The vertical indicator at C/Cₘₐₓ=0.1 indicates that dispersion losses would basically be negligible for current practical CPV designs). Not unexpectedly, dispersion losses increase with focal length and with concentration, but are far lower for GRIN lenses than for conventional homogeneous lenses. For example, at F=1.74 and C=1,300 the dispersion loss is only 1%. Unlike conventional lenses where chromatic aberration amplifies an intrinsically aberrated optic, the spherical GRIN lens starts aberration-free (geometrically) so that dispersion imposes a near-negligible loss (unless concentration approaching Cₘₐₓ is required).

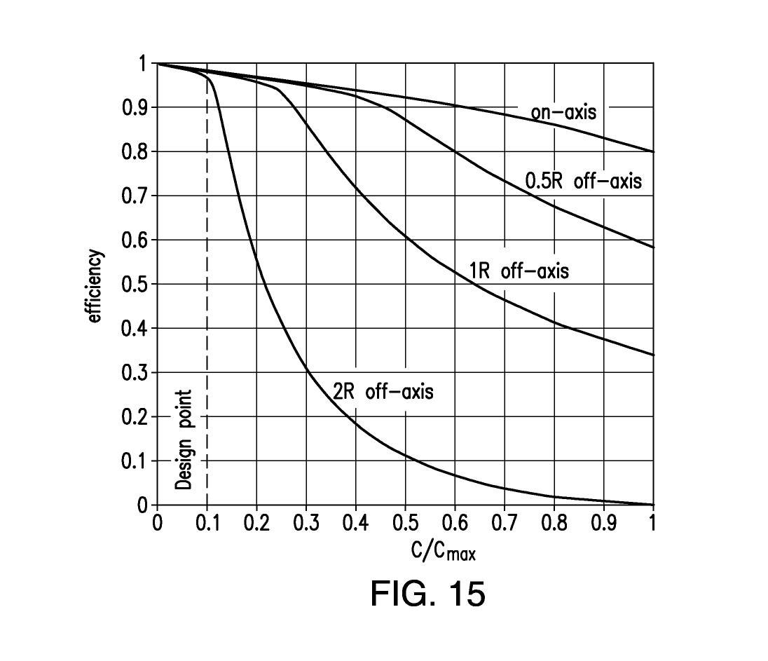

FIG. 15 quantifies sensitivity to absorber misalignment (or equivalently, a systematic error in the internal tracking motion of the lenses) (absorber displacement is in units of the minimum (θ=0) focal spot radius R; for the illustrative CPV scenario with C=1300 and C/Cₘₐₓ=0.1 (the vertical dotted line), R=0.15 mm). Efficiency-concentration curves were generated for a given translation of the absorber from its intended position in a F=1.74 system. For perspective, consider C≈1,300 (C/Cₘₐₓ≈0.1) with a solar cell 1 mm in diameter (so the lens diameter is ˜36 mm). The focal spot is noticeably smaller than the cell for most of the daily collection period. As a consequence, even sizable displacements result in a ray rejection of only ˜1-2%. Given the tolerance and robustness of current high-efficiency concentrator solar cells to markedly inhomogeneous flux maps, this result suggests the nominally stationary system has exceptional tolerance for optical errors with tracking by internal tracking devices.

Nominal stationarity comes at the price of a yearly-averaged cosine of the incidence angle less than unity, to with, ˜0.7 for a clear mid-latitude location [6] —a compromise unrelated to the optics. Close-packed lenses would incur ˜30% shading within the module, or one could markedly reduce shading by spacing them and accepting that ˜30% of the intercepted radiation misses the lenses as in FIGS. 10b and 10c (or intermediate arrangements).

In addition, high concentration forgoes acceptance of diffuse radiation [5, 6]. Stationary non-concentrating solar collectors benefit from diffuse collection, whereas the concentrators described herein collect essentially none (common to all CPV).

The absorber flux maps are non-uniform—most pronounced at normal incidence when the projected focal spot is smallest (FIG. 11). In principle, flux inhomogeneity augments solar cell series resistance losses. However, current commercial concentrator cells have exhibited efficiency decreases not exceeding measurement uncertainties at flux localization as acute as a few hundred percent [27-29].

For square (as opposed to circular) cells one approach is inscribing the design focal spot within the square and reducing averaged concentration by a factor of π/4—especially given the relative ease of attaining high irradiance such that avoiding a further loss in collection efficiency is paramount. The slight worsening in flux uniformity does not noticeably diminish the efficiency of the cells, and realizing concentration values of order 10³ would not be compromised. When flux uniformity is critical, kaleidoscopes [27] and Köhler integrators [32] can be added. Moreover, passive heat sinks can maintain cell temperatures at no more than ˜20-30 K above ambient temperature, at irradiance levels of thousands of suns, even with marked flux non-uniformities [27-29, 33].

Cost projections for the eventual mass production of the specific optical and internal tracking components portrayed here are approximate. The processed polymeric materials typically cost no more than a few US$ per kg—hence below US$100 per m² of aperture for modules of the type previously described. Automated fabrication costs of the order of US$0.1 per lens when billions are required (for GW-level power generation) are not unreasonable, amounting to roughly US$100 per m² of module aperture. Working experience with the types of precision delta robotic systems that would comprise the internal micro-tracker indicates that large-volume production at ˜US$100 per m² of module aperture is not unfeasible.

For photovoltaic concentration application, any of the spherical GRIN lens as described above that have focal length not smaller than 1 can be used, including the lenses that have constant-index core, constant shell or other profile having user-prescribed portion(s). A few examples of champion design of spherical GRIN lens are given below. They include truncated lenses that can obviate packing losses in solar modules without introducing incremental losses in collection efficiency and achieve a flux concentration ≈30000 (previously deemed unachievable with a single lens). Dispersion losses (due to a wavelength-dependent refractive index) were evaluated based on an AM1.5D solar spectrum and a Cauchy-type dispersion relation for the measured properties of representative polymer materials [2-4], for lenses designed based on the refractive indices at a wavelength of 633 nm. Unless otherwise noted, all the refractive index values as referenced in this application are based on this wavelength.

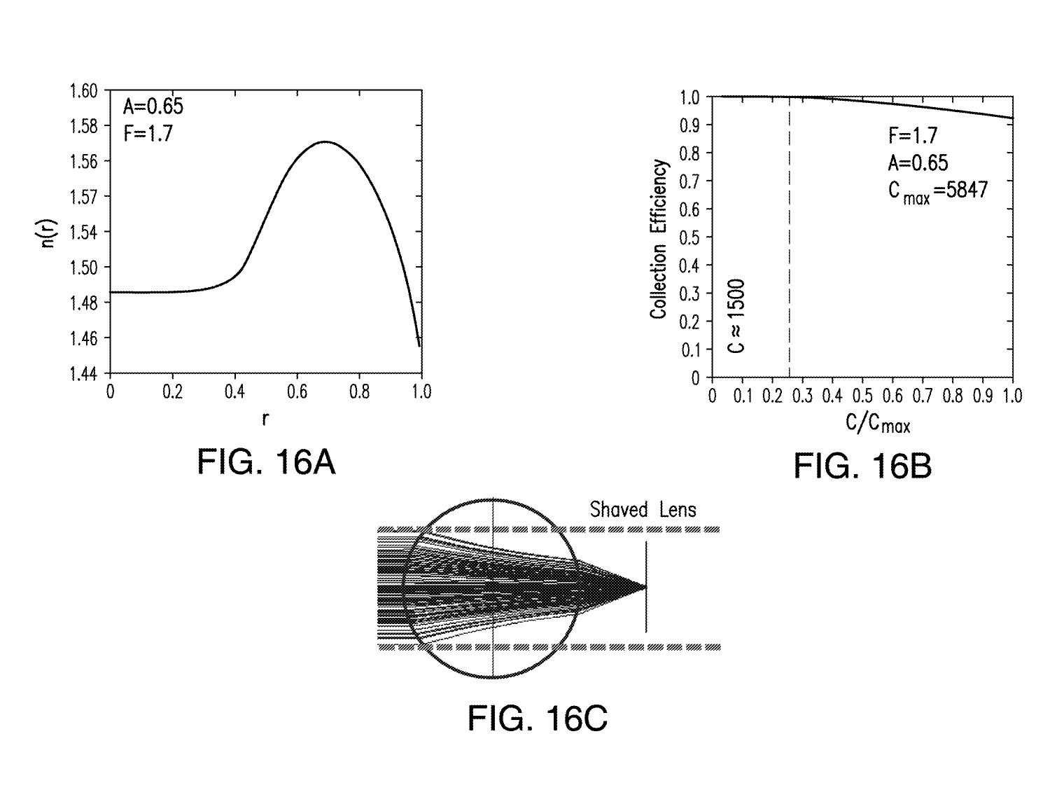

Designing for A<1 allows truncation of the lens in a form that eliminates packing losses in a typical rectangular module, at no incremental loss in collection efficiency—suitable for dual-axis tracking concentrator photovoltaics. FIG. 16 presents one champion design that also includes a constant-index core. FIG. 16(a) shows n(r) for a spherical GRIN lens suitable for solar concentrator, with F=1.7 and A=0.65; 16(b) shows efficiency-concentration curve characterizing lens performance. The geometric efficiency does not account for material-related Fresnel reflection and absorption, which are case-specific and readily incorporated. The abscissa refers to concentration C relative to the thermodynamic limit Cₘₐₓ={A/(F Sin(θₛᵤₙ))}² which in this case is 5847. A realistic concentrator design that accounts for liberal optical tolerance to off-axis orientation augurs designing for C≈1500 [30] for which C/Cₘₐₓ≈0.26 and the geometric collection efficiency is basically 100%; 16(c) shows raytrace simulation (LightTools®, Synopsys Inc.) with a polychromatic, extended solar source (5 mrad effective solar angular radius θₛᵤₙ comprising the intrinsic solar disc convolved with lens inaccuracies), illustrating how a non-full aperture GRIN solution can be “shaved” (i.e., the spherical caps of the lens outside of the aperture is symmetrically truncated, resulting in two (upper and lower) flat surfaces) at no loss of collectible radiation. 50000 rays uniformly distributed spatially and in projected solid angle were traced for each of 12 wavelengths spanning the solar spectrum.

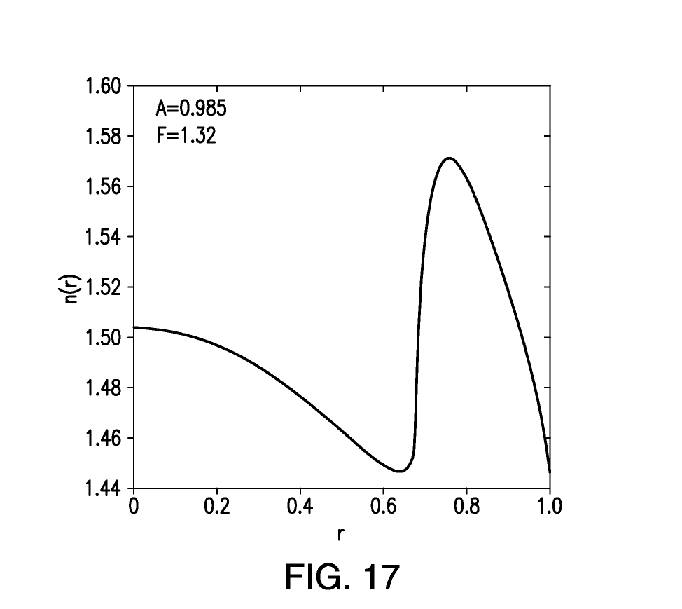

FIG. 17 illustrates the n(r) of another champion design (F=1.32 and A=0.985, the latter incurring a 3% loss of collectible radiation because of collector stationarity). Geometric collection efficiency=95% at C=1500 (C=1500 is chosen to provide liberal off-axis tolerance based on Cₘₐₓ=22,730) integrated over the full 100° acceptance angle, including losses due to the polychromatic and extended solar source. If for convenience one approximates n(r) as constant over 0≦r≦0.15, the lens performance is essentially unaffected.

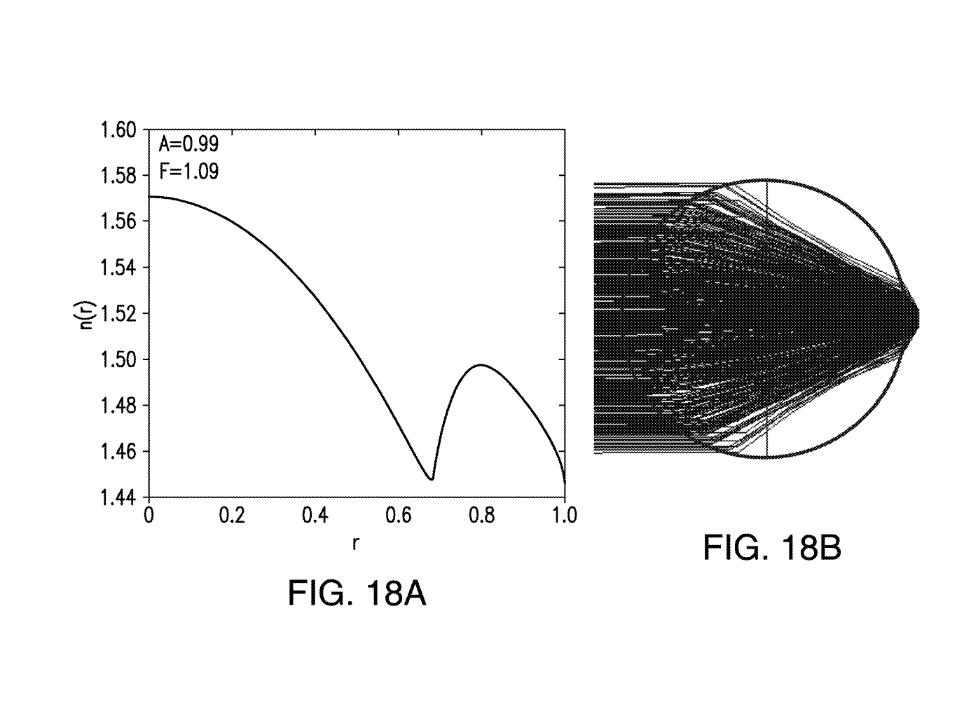

FIG. 18 presents a further champion design whose n(r) can produce a solar flux concentration exceeding 30000 at the center of its focal spot—an irradiance level heretofore deemed unattainable with a single lens for broadband radiation. (FIG. 18a shows the n(r) profile for F=1.09 and A=0.99, for which Cₘₐₓ=33000; FIG. 18b shows raytrace for an extended, polychromatic solar source.) Although dispersion losses result in some of the radiation falling outside the ultra-high irradiance region, it is demonstrated here that such enormous flux densities can be produced at all—of value in nanomaterial synthesis and concentrator solar cell characterization [34].

The high performance potential of the optical strategy discussed here can also apply to 2D systems, i.e., line-focus cylindrical GRIN lenses, albeit with attainable concentration being roughly the square root of the 3D values. The efficiency-concentration characteristics can be slightly better because the dilution of absorber power density is less pronounced in 2D. Alternatively, hemispherical GRIN lenses with suitable refractive index profiles can also be used for solar modules, which can be an integral part of the planar cover glazing. With current and projected CPV applications focusing on concentration levels from hundreds to the order of 10³ suns, detailed analyses were restricted here to 3D systems.

Solar concentrators described herein can also be used to focus light on an optical fiber and deliver natural light for indoor lighting applications. They can further be combined with a cylinder with the same gradient index of refraction and offer two-dimensional solar concentration by focusing light on a strip close to the thermodynamic limit of solar concentration, and thus would be suitable for solar thermal applications.

The spherical GRIN lenses as described herein can also be used in the non-stationary system currently being used. Accordingly, a system for photovoltaic solar concentration is provided, which includes an absorber including a photovoltaic cell having a light receiving surface; a spherical GRIN lens, wherein the photovoltaic cell is placed at a distance from the center of the GRIN lens, the distance being equal to the focal length of the GRIN lens for the sun, and a tracking device operatively coupled to the GRIN lens and the photovoltaic cell, the tracking device being capable of moving the GRIN lens to track the trajectory of the sun and moving the photovoltaic cell such that the line connecting the center of the GRIN lens and the center of the sun is always normal to the light receiving surface of the solar cell. Again, in this system, the GRIN lens can be a nominally perfect imaging GRIN lens, or any of the various GRIN lenses described above.

Besides photovoltaic concentration, the various above-described spherical GRIN lenses can be used in a wide array of applications, for example, they can be incorporated as an optic component of one of an imaging system (e.g., an infrared imaging system, a camera, a microscope, a telescope), an illumination system, and other devices where high concentration of light, short focal length, and perfect imaging are desired or needed. They can also be used in applications where the role of object and image (source and target) are interchanged relative to the flux concentration applications, such as a collimator.

Below is a listing of the references cited herein whose sequence number have been set forth in square brackets in this application (the disclosures of these references are herein incorporated by reference):
1. R. K. Luneburg, The Mathematical Theory of Optics (U. California Press, Berkeley, 1964).
2. Y. Jin, H. Tai, A. Hiltner, E. Baer, and J. S. Shirk, “New class of bioinspired lenses with a gradient refractive index,” J. Appl. Polymer Sci. 103, 1834-1841 (2007).
3. G. Beadie, J. Shirk, A. Rosenberg, P. Lane, E. Fleet, A. Kamdar, Y. Jin, M. Panting, T. Kazmierczak, Y. Yang, A. Hiltner, and E. Baer, “Optical properties of a bio-inspired gradient refractive index polymer lens,” Opt. Express 16, 11540-11547 (2008).
4. M. Ponting, A. Hiltner, and E. Baer, “Polymer nanostructures by forced assembly: process, structure and properties,” Macromol. Symp. 294, 19-32 (2010).
5. R. Winston, P. Benitez, and J. C. Miñano, with contributions from N. Shatz and J. Bortz, Nonimaging Optics (Elsevier, Oxford, 2005).
6. A. Rabl, Active Solar Collectors and Their Applications (Oxford U. Press, NY, 1985).
7. K. Araki, T. Yano, and Y. Kuroda, “30 kW concentrator photovoltaic system using dome-shaped fresnel lenses,” Opt. Express 18, A53-A63 (2010).
8. W. Nishikawa, E. Green, and S. Crowley, “Energy production of CPV power plants at ISFOC,” Proc. ICSC-5, 5th Int. Conf. on Solar Concentrators for the Generation of Electricity or Hydrogen, Palm Desert, Calif. (2008).
9. Edmund Optics Inc., 101 E. Gloucester Pike, Barrington, N.J. 08007, “High precision linear actuators” (2010).
10. P. Kotsidas, E. Chatzi, and V. Modi, “Stationary nonimaging lenses for solar concentration,” Appl. Opt. 49, 5183-5191 (2010).
11. J. M. Gordon, “Spherical gradient-index lenses as perfect imaging and maximum power transfer devices,” Appl. Opt. 39, 3825-3832 (2000).
12. A. Fletcher, T. Murphy, and A. Young. “Solutions of two optical problems,” Proc. Roy. Soc. Lond. A Mat. 223, 216-225 (1954).
13. S. P. Morgan. “General solution of the Luneberg lens problem,” J. Appl. Phys. 29, 1358-1368 (1958).
14. J. C. Maxwell, “On the general laws of optical instruments,” Quart. J. Pure Appl. Math. 2, 233-247 (1854).
15. C. Ye and R. McLeod, “GRIN lens and lens array fabrication with diffusion-driven photopolyrner,” Opt. Lett. 33, 2575-2577 (2008).
16. Sochacki, J. Flores, and C. Gómez-Reino, “New method for designing the stigmatically imaging gradient-index lenses of spherical symmetry,” Appl. Opt. 31, 5178-5183 (1992).
17. A. D. Polyanin and A. V. Manzhirov, Handbook of Integral Equations, 2nd Ed. (Chapman and Hall/CRC Press, Boca Raton, 2008).
18. C. T. H. Baker, The Numerical Treatment of Integral Equations (Clarendon Press, Oxford, 1977).
19. R. Estrada and R. P. Kanwal, Singular Integral Equations (Birkhäuser, Boston, 2000).
20. S. Twomey, “On the numerical solution of Fredholm integral equations of the first kind by the inversion of the linear system produced by quadrature,” J. Assoc. Comput. Mach. 10, 97-101 (1963).
21. D. L. Phillips, “A technique for the numerical solution of certain integral equations of the first kind,” J. Assoc. Comput. Mach. 9, 84-97 (1962).
22. L. N. Trefethen, Spectral Methods in Matlab (S.I.A.M., Philadelphia, 2000).
23. Matlab v. 7.9 and online documentation: http://www.mathworks.com/help/techdoc/ref/quadgk.html (MathWorks Inc., Natick, Mass., 2003).
24. D. Feuermann, J. M. Gordon, and M. Huleihil, “Solar fiber-optic mini-dish concentrators; first experimental results and field experience,” Solar Energy 72, 459-472 (2002).
25. A. W. Bett and H. Lerchenmiiller, “The Flatcon system from Concentrix Solar,” in: Concentrator Photovoltaics, A. Luque, V. M. Andreev (Eds.) Springer, Berlin (Ch. 14), pp. 301-320 (2007).
26. M. Yamaguchi, K. Araki, and T. Takamoto, “Concentrator solar cell modules and systems developed in Japan,” in: Concentrator Photovoltaics, A. Luque, V. M. Andreev (Eds.) Springer, Berlin, (Ch. 15), pp. 321-340 (2007).
27. J. M. Gordon, E. A. Katz, D. Feuermann, and M. Huleihil, “Toward ultra-high-flux photovoltaic concentration,” Appl. Phys. Lett. 84, 3642-3644 (2004).
28. E. A. Katz, J. M. Gordon, W. Tassew, and D. Feuermann, “Photovoltaic characterization of concentrator solar cells by localized irradiation,” J. Appl. Phys. 100, 044514 (2006).
29. O. Korech, B. Hirsch, E. A. Katz, and J. M. Gordon, “High-flux characterization of ultra-small multi-junction concentrator solar cells,” Appl. Phys. Lett. 91, 064101 (2007).
30. A. Goldstein and J. M. Gordon, “Tailored solar optics for maximal optical tolerance and concentration,” Solar Energy Mater. Solar Cells 95, 624-629 (2011).
31. J. Q. Xi, Martin F. Schubert, J. K. Kim, E. F. Schubert, M. Chen, S. Y. Lin, W. Liu, and J. A. Smart, “Optical thin-film materials with low refractive index for broadband elimination of Fresnel reflection,” Nature Photonics 1, 176-179 (2007).
32. P. Benitez, J. C. Miñano, P. Zamora, R. Mohedano, A. Cvetkovic, M. Buljan, J. Chaves, and M. Hernandez, “High performance Fresnel-based photovoltaic concentrator,” Opt. Express 18, A25-A40 (2010).
33. J. Sun, T. Israeli, T. A. Reddy, K. Scoles, J. M. Gordon, and D. Feuermann, “Modeling and experimental evaluation of passive heat sinks for miniature high-flux photovoltaic concentrators,” J. Sol. Energy Eng. 127, 138-145 (2005).
34. J. M. Gordon, D. Babai, and D. Feuermann, “A high-irradiance solar furnace for photovoltaic characterization and nanomaterial synthesis”, Solar Energy Mater. Solar Cells 95, 951-956 (2011).

The description herein merely illustrates the principles of the disclosed subject matter. Various modifications and alterations to the described embodiments will be apparent to those skilled in the art in view of the teachings herein. Further, it should be noted that the language used herein has been principally selected for readability and instructional purposes, and can not have been selected to delineate or circumscribe the inventive subject matter. Accordingly, the disclosure herein is intended to be illustrative, but not limiting, of the scope of the disclosed subject matter.

What is claimed is:

1. A spherical gradient index (GRIN) lens having a radius and a radially symmetric refractive index profile n(r), where r is the radial position within the lens and 0≦r≦1, wherein n(r) satisfies the following: there exist rₐ and r_{b}, 0<rₐ<r_{b}<1, such that n(0)>n(rₐ), n(r_{b})>n(rₐ), and n(r_{b})>n(1).

2. The spherical GRIN lens of claim 1, wherein further n(0)>n(r_{b}).

3. The spherical GRIN lens of claim 1, wherein further n(0)<n(r_{b}).

4. The spherical GRIN lens of claim 1, wherein further n(r) is substantially constant for 0≦r≦C₁, wherein C₁ is a real number from about 0.05 to about 0.95.

5. The spherical GRIN lens of claim 1, wherein further there exists r_{c}, where r_{b}<r_{c}<1, such that n(r) over the range of r_{c}≦r≦1 is substantially constant.

6. A spherical gradient index (GRIN) lens having a radius and a radially symmetric refractive index profile n(r), where r is the radial position within the lens and 0≦r≦1 wherein n(r) is substantially constant in the range of 0≦r≦C₂, wherein C₂ is a real number from about 0.05 to about 0.9.

7. The spherical GRIN lens of claim 6, wherein C₂ is from about 0.1 to about 0.6.

8. The spherical GRIN lens of claim 6, wherein further there exists r_{d}, C₂<r_{d}<1, such that n(r_{d})>n(C₂).

9. The spherical GRIN lens of claim 8, wherein further n(r_{d})>n(1).

10. The spherical GRIN lens of claim 6, wherein further n(1)>1.

11. The spherical GRIN lens of claim 6, wherein further n(r) has a maximum value nₘₐₓ, and a minimum value nₘᵢₙ, and wherein the nₘₐₓ−nₘᵢₙ≦0.3.

12. The spherical GRIN lens of claim 11, wherein nₘₐₓ−nₘᵢₙ≦0.13.

13. The spherical GRIN lens of claim 11, wherein nₘₐₓ is in the range of from about 1.4 to about 2.

14. The spherical GRIN lens of claim 11, wherein the entire n(r) over the range of 0≦r≦1 is mathematically derived from a given set of input parameters including an aperture of the lens, a desired focal length of the lens, and n(1), such that the spherical GRIN lens as a whole produces nominally perfect imaging.

15. The spherical GRIN lens of claim 1, wherein n(r) includes at least two portions depending on r:
(1) a user prescribed portion for r_{A}≦r≦r_{B}, wherein r_{A} and r_{B}ε(0,1);
(2) a portion for 0<r<r_{A} and r_{B}<r<1, where n(r) is mathematically derived from a set of input parameters including an aperture of the lens and a desired focal length of the lens such that the spherical GRIN lens as a whole produces nominally perfect imaging.

16. The spherical GRIN lens of claim 15, wherein the user prescribed portion is a constant over r_{A}≦r≦r_{B}.

17. The spherical GRIN lens of claim 15, wherein the user prescribed portion is a linear or non-linear function over r_{A}≦r≦r_{B}.

18. The spherical GRIN lens of claim 15, wherein 0<r_{A}<C₃, C₃ is a real number in the range of about 0.6 to about 0.95, and r_{B}=1.

19. The spherical GRIN lens of claim 1, made of one or more materials whose refractive index is in the range of about 1.1 to about 2.0.

20. The spherical GRIN lens of claim 1, made of one or more polymeric materials.

21. The spherical GRIN lens of claim 1, having an aperture of smaller than 1.

22. The spherical GRIN lens of claim 21, wherein spherical caps of the lens outside of the aperture is symmetrically truncated.

23. The spherical GRIN lens of claim 1 having a focal length greater than or equal to 1 relative to the radius of the GRIN lens.

24. The spherical GRIN lens of claim 1 having a focal length smaller than 1 relative to the radius of the GRIN lens.

25. The spherical GRIN lens of claim 1 that produces nominally perfect imaging.

26. The spherical GRIN lens of claim 1, incorporated as an optic component of one of an imaging system, a camera, a microscope, a telescope, a collimator, and an illumination system.

27. A method for obtaining a radially symmetric refractive index profile n(r) of a spherical GRIN lens having a radius, where r is the radial position within the lens and 0≦r≦1, the method comprising:
providing a value for each of a set of input parameters including n(1), a focal length of the lens and an aperture of the lens; and
using a computer apparatus, numerically determining n(r) based on the provided values for the set of input parameters, such that the lens produces nominally perfect imaging.

28. The method of claim 27, wherein the value provided for the refractive index of the surface of the lens is greater than 1.

29. The method of claim 27, wherein the value provided for the aperture of the lens is smaller than 1.

30. A method for obtaining a radially symmetric refractive index profile n(r) of a spherical GRIN lens having a radius, where r is the radial position within the lens and 0≦r≦1, the method comprising:
providing a predefined function for a range of r_{A}≦r≦r_{B};
providing a value for each of a set of input parameters, the parameters including a focal length of the lens and an aperture of the lens; and
using a computer apparatus, numerically determining n(r) for the remaining range of r based on the provided values for the set of input parameters, such that the lens produces nominally perfect imaging.

31. A system for photovoltaic solar concentration, comprising:
a stationary absorber including a photovoltaic cell;
a spherical gradient index (GRIN) lens, wherein the photovoltaic cell is placed at a distance from the center of the GRIN lens, the distance being equal to the focal length of the GRIN lens for the sun, and
a tracking device operatively coupled to the GRIN lens, the tracking device being capable of moving the GRIN lens to track the trajectory of the sun while maintaining the distance.

32. The system of claim 31, wherein the system further includes a backing plate having a surface to which the photovoltaic cell is affixed.

33. The system of claim 32, wherein the backing plate comprises a heat sink.

34. The system of claim 31, further comprising a housing which encloses the stationary absorber, the GRIN lens, and the tracking device.

35. The system of claim 31, wherein the spherical GRIN lens produces nominally perfect imaging.

36. The system of claim 31, wherein the spherical GRIN lens is a spherical GRIN lens according to claim 1.

37. The system of claim 31, wherein the geometric concentration of the system is up to about 30000.

38. The system of claim 31, wherein the focal length of the spherical GRIN lens is greater than 1.73 relative to the radius of the lens.

39. A method of utilizing solar energy, comprising:
placing a photovoltaic cell at a distance from the center of a spherical GRIN lens, the distance being equal to the focal length of the GRIN lens for the sun; and
moving the GRIN lens to track the trajectory of the sun while maintaining the distance, wherein the photovoltaic cell is kept stationary during moving the GRIN lens.

40. The method of claim 39, wherein the GRIN lens is a nominally perfect imaging GRIN lens.

41. The method of claim 39, wherein the GRIN lens is a GRIN lens according to claim.

42. A system for photovoltaic solar concentration, comprising:
an absorber including a photovoltaic cell having a light receiving surface;
a spherical gradient index (GRIN) lens, wherein the photovoltaic cell is placed at a distance from the center of the GRIN lens, the distance being equal to the focal length of the GRIN lens for the sun, and
a tracking device operatively coupled to the GRIN lens and the photovoltaic cell, the tracking device being capable of moving the GRIN lens to track the trajectory of the sun and moving the photovoltaic cell such that the line connecting the center of the GRIN lens and the center of the sun is always normal to the light receiving surface of the photovoltaic cell.

43. The method of claim 42, wherein the GRIN lens is a nominally perfect imaging GRIN lens.

44. The method of claim 42, wherein the GRIN lens is a GRIN lens according to claim 1.
